(19) United States
(12) Patent Application Publication
(10) Pub. No.: US 2014/0058699 A1
(43) Pub. Date: Feb. 27, 2014

(54) INFORMATION PROCESSING APPARATUS, TEST DATA GENERATING APPARATUS, AND TEST DATA GENERATING METHOD

(71) Applicant: FUJITSU LIMITED, Kawasaki-shi (JP)

(72) Inventor: Hiroshi OKAMOTO, KANAZAWA (JP)

(73) Assignee: FUJITSU LIMITED, Kawasaki-shi (JP)

(21) Appl. No.: 13/959,771

(22) Filed: Aug. 6, 2013

(30) Foreign Application Priority Data
Aug. 27, 2012 (JP) 2012-187057

(51) Int. Cl. G01R 31/28

(52) U.S. Cl. CPC G01R 31/2851
USPC 702/118

(57) ABSTRACT

An apparatus has a first operation model containing connection information indicating a connecting relation between pins of the integrated circuits including a first integrated circuit and a second integrated circuit and containing a designation of an output pin for outputting data to the outside of the first integrated circuit or a designation of an input pin for inputting the data from the outside of the first integrated circuit, and a second operation model containing a designation of the output pin or the input pin outside the second integrated circuit and having a definition of an interface specification for inputting and outputting the data to the input pin and the output pin of the second integrated circuit via the communication pin.

### CROSS-REFERENCE TO RELATED APPLICATION

This application is based upon and claims the benefit of priority of the prior Japanese Patent Application No. 2012-187057, filed on Aug. 27, 2012, the entire contents of which are incorporated herein by reference.

### FIELD

The embodiments discussed herein are related to a connection test between integrated circuits.

### BACKGROUND

The integrated circuit mounted on a printed circuit board has hitherto been mounted with, e.g., a test interface called a JTAG (Joint Test Action Group). Then, a test of the printed circuit board is implemented by inputting and outputting signals according to this interface system. In this case, the test of the printed circuit board is implemented by generating a test program on the basis of a connecting relation between the integrated circuits on the printed circuit board, translating the test program, inputting a test pattern to the printed circuit board from a tester and checking a response.

### DOCUMENTS OF PRIOR ARTS

### Patent Document

[Patent document 1] Japanese Laid-Open Patent Publication No. 2000-242573
[Patent document 2] Japanese Laid-Open Patent Publication No. 09-218248

### SUMMARY

One aspect of the embodiment of the disclosure is exemplified by a test data generating apparatus which generates test data of an electronic device including a first integrated circuit and a second integrated circuit. The second integrated circuit has at least one communication pin. The test data generating apparatus includes:

a storage unit storing connection information indicating a connecting relation between pins of the integrated circuit within the electronic device including the first integrated circuit and the second integrated circuit; a first operation model storage unit containing at least one of a designation of an output pin for outputting data to the outside of the first integrated circuit and a designation of an input pin for inputting data from the outside of the first integrated circuit; and a second operation model storage unit containing at least one of a designation of an output pin for outputting data to the outside of the second integrated circuit and a designation of an input pin for inputting data from the outside of the second integrated circuit, and having a definition of an interface specification for inputting and outputting the data to the input pin and the output pin of the second integrated circuit via the communication pin.

The test data generating apparatus further includes a generation unit to generate control information for transferring and receiving the data to and from the first integrated circuit according to the predetermined specification and to generate control information according to the interface specification for executing at least one of writing the data to the output pin and reading the data from the input pin via the communication pin.

The object and advantages of the invention will be realized and attained by means of the elements and combinations particularly pointed out in the claims. It is to be understood that both the foregoing general description and the following detailed description are exemplary and explanatory and are not restrictive of the invention.

### BRIEF DESCRIPTION OF DRAWINGS

FIG. 1 is a diagram of one example of a circuit on a printed circuit board having an LSI mounted with a JTAG circuit according to a comparative example 1;

FIG. 2 is a diagram of one example of a circuit of the printed circuit board on which a JTAG component and a component not mounted with the JTAG circuit exist in mixture;

FIG. 3 is a diagram illustrating a circuit in which the component mounted with the JTAG circuit in FIG. 2 and a connecting portion of the component not mounted with the JTAG circuit are enlarged;

FIG. 4 is a diagram illustrating how a test program is generated based on simulation according to a comparative example 2;

FIG. 5 is a diagram illustrating a process of a JTAG test generator;

FIG. 6 is a diagram illustrating an I2C component included on a test target printed circuit board;

FIG. 7 is a diagram of an example of connecting the I2C component;

FIG. 8 is a diagram illustrating an example of data designated by a control sequence for controlling the I2C component;

FIG. 9 is a diagram illustrating a process of generating test program for the printed circuit board including the I2C components according to an example 1;

FIG. 10 is a diagram illustrating a structure of an operation model 23 of the I2C component;

FIG. 11 is a diagram illustrating a connection between the I2C components;

FIG. 12 is a diagram depicting an output image of an I2C tree 25;

FIG. 13 is a diagram illustrating a processing flow of generating the I2C tree;

FIG. 14 is a diagram depicting a storage image of test access information;

FIG. 15 is a diagram illustrating a circuit in which a parallel test pattern is generated;

FIG. 16 is a diagram illustrating the parallel test pattern;

FIG. 17 is a diagram illustrating a test database;

FIG. 18 is a diagram illustrating a flow of the data in a process of generating a final test pattern;

FIG. 19A is a diagram illustrating a processing flow of generating the final test pattern;

FIG. 19B is a diagram illustrating a flow of generating a final I2C function test;

FIG. 20 is a diagram illustrating details of an I2C final test pattern outputting process;

FIG. 21 is a diagram illustrating short-circuit of a net that connects pins of the JTAG component.

### DESCRIPTION OF EMBODIMENTS

An information processing apparatus according to one embodiment will hereinafter be described with reference to the drawings. A configuration of the following embodiment is an exemplification, and the present apparatus is not limited to the configuration of the embodiment.

### Comparative Example 1

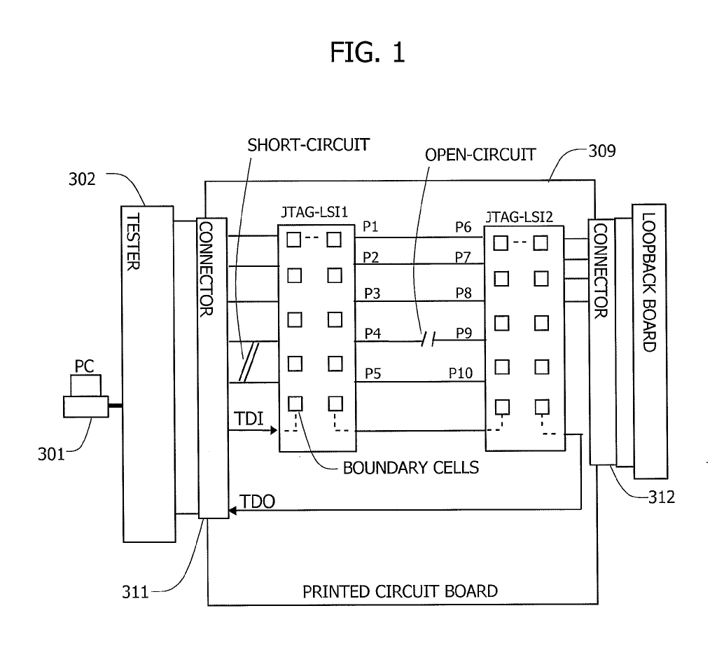

The information processing apparatus according a comparative example will hereinafter be described with reference to the drawings in FIGS. 1 through 4. The comparative example will discuss a test of a printed circuit board including components having test circuits (JTAG circuit) pursuant to JTAG (Joint Test Action Group) Standards. FIG. 1 illustrates one example of a circuit test of a printed circuit board 309 including LSIs (Large Scale Integrations) mounted with JTAG circuits. The circuitry in FIG. 1 is exemplified to include the test target printed circuit board 309, an information processing apparatus 301 that generates a test program and manages the test, and a tester 302 that implements the test of the printed circuit board 309 according to the test program generated by the information processing apparatus 301. In this example, the tester 302 establishes a connection to a connector 311 of the printed circuit board 309, inputs and outputs signals, and thus implements the test. The test program connotes, e.g., a chain of commands etc for controlling the test, which are input to the tester 302 when testing the printed circuit board 309. The tester 302, according to the test program, inputs a bit string to the printed circuit board 309 via the connector 311 and acquires the bit string from the printed circuit board 309 via the connector 311. Further, the test program contains test data such as expected values etc for checking the acquired bit string.

The printed circuit board 309 includes two components such as JTAG-LSI1 and JTAG-LSI2 each mounted with, e.g., the JTAG test circuit. Respective terminals of the JTAG-LSI1 and JTAG-LSI2 are connected to internal boundary cells. The component mounted with the JTAG test circuit will hereinafter be called a JTAG component. The terminal is also called a pin. The JTAG-LSI1 and JTAG-LSI2 are given as one example of a first integrated circuit.

The JTAG component has a configuration to execute a procedure named a boundary scan. The boundary scan is one example of a predetermined specification. The JTAG component includes boundary cells between the component pins and internal core logic. The data on the pins of the JTAG component can be read to the boundary cells. Further, values set in the boundary cells are writable onto the pins. The boundary cells connected to the respective pins take a form of a register group capable of sequentially shifting the values. In semantics, the boundary cell is also called a boundary scan register.

Moreover, a TDI (Test Data Input) pin is connected to one side of the arrangement of the boundary cells with the data being shifted, and a TDO (Test Data Output) pin is connected to the other side. An EXTEST command is set in the JTAG component, then a TAP state (which will hereinafter be simply termed the state) is made to transition to a capture DR, and the tester 302 can capture the data of the pins into the boundary cells by transmitting TCK next. The state of the JTAG component is made to transition to a shift DR, and the tester 302 can send the new data into the boundary cells via the TDI each time TCK is transmitted next. Further, the captured data can be simultaneously shifted and output to the TDO. At a stage of arranging the predetermined data in the boundary cells from the TDI, the state of the JTAG component is made to transition to an update DR, and the tester 302 can output the data of the boundary cells to the pins by transmitting the TCK next.

The TDI pin and the TDO will hereinafter be simply called the TDI and TDO.

The TDI signals output from the tester 302 are set in the internal boundary cells of the JTAG-LSI1 via the TDI within the board from the connector 311. Further, the signals are shifted between the internal boundary cells of the JTAG-LSI1 and read to the JTAG-LSI2. Still further, the signals are shifted between the internal boundary cells of the JTAG-LSI2 and observed from the TDO. Moreover, the signals between the JTAG-LSI1 and JTAG-LSI2 are shifted in from the TDI and set as output signals of the JTAG-LSI1. Then, the output signals of the JTAG-LSI1 are handed over to pins P6-P10 of the JTAG-LSI2 from pins P1-P5. The signals handed over to the pins P6-P10 of the JTAG-LSI2 are accepted by the internal boundary cells of the JTAG-LSI2. The signals accepted by the internal boundary cells of the JTAG-LSI2 are shifted between the internal boundary cells of the JTAG-LSI2 and observed by the TDO. Moreover, in the signals between the connector 311 and the JTAG-LSI1, the signals output from the tester 302 are received and shifted in the boundary cells of the JTAG-LSI1 and observed by the TDO via the boundary cells of the JTAG-LSI2. Note that the signals between the JTAG-LSI2 and the connector 312 are tested through a loopback board.

Failures such as short-circuit and open-circuit (disconnection) of the midway path are detected by the test described above. Input information for generating the test program described above involves using a BSDL (Boundary-Scan Description Language) file and a net list. The BSDL file contains a description of an associated relation between the pins and the boundary cells and a description of input/output designations of the pins as the internal information of the JTAG component. Further, the net list contains a description of a connecting relation between the pins of the components mounted on the printed circuit board 309 and a description of an associated relation between names and model rating numbers of the components on the printed circuit board 309. The model rating number will hereinafter be simply referred to also as the model or the model number. The net list is stored in a single file in many cases. The generation of the test program of the JTAG component involves employing a JTAG test generator. The information processing apparatus 1 executes, for functioning as the JTAG test generator, a computer program deployed in an execution-enabled mode on a main memory.

An analysis of the two files, i.e., the BSDL file and the net file enables the JTAG test generator to determine a test pattern as to which pin is driven per signal and which pin the signal is received by. The JTAG test generator can automatically determine what number of times (e.g., N1 times) the data are shifted between the boundary cells, which are input from the TDI, in order to output the signals from a certain pin of the JTAG on the basis of the determined test pattern. Next, the JTAG test generator can also automatically determine what number of times (e.g., N2 times) the signal is shifted, which is captured by the boundary cell connected to a corresponding pin of the connector 311, in order to observe a value input to a corresponding pin connecting with the pin to which the signal is output at the pin TDO of the connector 311. With this method, the JTAG test generator determines the test pattern of the printed circuit board 309 mounted with the JTAG components and can automatically generate the test program.

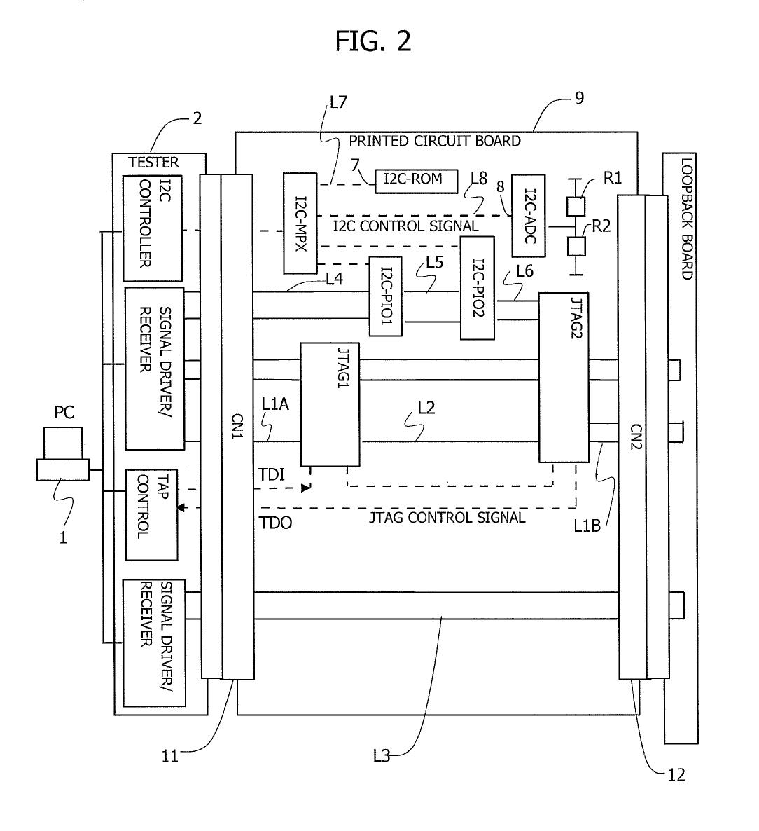

FIG. 2 illustrates one example of the test circuit of the printed circuit board 309 on which the JTAG component and the component not mounted with the JTAG test circuit exist in mixture. FIG. 2 illustrates a test target printed circuit board 9, the information processing apparatus 1 that generates the test program and manages the test, and a tester 2 that implements the test for the printed circuit board 9 according to the test program generated by the information processing apparatus 1.

The information processing apparatus 1 is a computer including a main memory or the like, an external storage device, a display device, an input device, a communication interface and so on. Further, the information processing apparatus 1 may include a device or the like that accesses a removable storage medium.

Moreover, the tester 2 is an electronic circuit including a communication interface with the information processing apparatus 1 and a connection interface to the printed circuit board 9. The tester 2 has an I2C controller, a signal driver receiver and a TAP (Test Access Port) control unit. The I2C controller is a communication unit performing communications with an I2C component on the printed circuit board 9. The I2C controller performs the communications with the I2C component via an I2C interface according to a control sequence specified in the I2C.

The signal driver is a data transmitting/receiving unit that transmits and receives the normal data other than the test pattern to and from each of the components via PIO etc.

The TAP control unit controls the transfer and the reception of the data with respect to the pin of the JTAG component called TAP. The TAP includes the respective pins of the TDI (Test Data Input), the TDO (Test Data Output), a TMS (Test Mode Select), a TCK (Test Clock) and a TRST (Test Reset) of the JTAG component.

In the example of FIG. 2, components equipped with the I2C interfaces are mounted other than the JTAG components. The component equipped with the I2C interface will hereinafter be called an I2C component. FIG. 2 illustrates two pieces of JTAG components (JTAG1, JTAG2). Dotted lines extending from lower portions of the two JTAG components represent controls signals (TDI/TDO etc) of the JTAG components. Further, solid lines connecting with the JTAG components represent wires led from the pins connected to the boundary cells.

Moreover, in the example of FIG. 2, five pieces of I2C components are given as an I2C-PIO1 (Programmable Input-Output 1), an I2C-PIO2, an I2C-MPX (Multiplexer), an I2C-ROM (Read Only Memory) and an I2C-ADC (Analog Digital Converter). Herein, the I2C-PIO1 and the I2C-P102 are called such as program I/O chips, program I/O components, program I/O modules and program logics. The I2C-PIO1 etc accepts the inputs of the control signals in accordance with the control sequence from the I2C interface, and inputs and outputs the digital data from I/O ports. The I2C-MPX selects one of a plurality of channels according to the control sequence from the I2C interface. The host device such as the tester 2 performs the communications with the I2C-PIO via the I2C interface, and inputs and outputs the digital data from the I/O ports. Moreover, the host device such as the tester 2 performs the communications with the I2C-PIO on the channel selected by the I2C-MPX, and inputs and outputs the digital data from the I/O ports. The I2C-ROM, according to the control sequence given from the I2C interface, accepts the input of the control signal, then reads the data from the ROM and outputs the data to the I2C interface. The I2C-ADC, according to the control sequence given from the I2C interface, accepts the input of the control signal, then converts the analog input signals into the digital data and outputs the digital data to the I2C interface.

Dotted lines connecting with the respective I2C components represent I2C control signals. Further, solid lines connecting with the I2C components represent wires extending from the pins of the PIO (Programmable Input/Output) under the control of the respective components.

By the way, the following are portions where the JTAG test generator can automatically generate the test pattern for the printed circuit board 9. A first portion is a connecting portion between the connector and the JTAG component and corresponds to a portion connected by wires L1A, L1B in FIG. 2. A second portion is a connecting portion between the JTAG component and the JTAG component, and corresponds to a portion connected by a wire L2 in FIG. 2. A third portion is a connecting portion between the connector and the connector, and corresponds to a portion connected by a wire L3 in FIG. 2.

On the other hand, the components such as the I2C components other than the JTAG components are not pursuant to the JTAG standards and are therefore the components unknown from the JTAG test generator. Accordingly, the JTAG test generator is unable to automatically generate the test program of the circuits including the components other than the JTAG components. The following are portions that can be exemplified as the portions where the JTAG test generator cannot automatically generate the test program.

A first portion is a connecting portion between the connector and the I2C component and corresponds to a portion connected by a wire L4 in FIG. 2. A second portion is a connecting portion between the I2C component and the I2C component, and corresponds to a portion connected by a wire L5 in FIG. 2. A third portion is a connecting portion between the I2C component and the JTAG component, and corresponds to a portion connected by a wire L6 in FIG. 2. A fourth portion is a pin 7 of the I2C interface of the ROM (Read Only Memory). Fifth portions are a pin 8 of the I2C interface of an ADC (Analog Digital Converter) and an ADC input pin.

A method of testing the I2C component as one example of the component different from the JTAG test circuit will hereinafter be described by way of a comparative example.

The control of the I2C interface can be attained by conducting the control in a way that uses a dedicated controller mounted with an I2C controller element on the side of the tester 2 or by executing a chain of sequences of the I2C in a way that uses tester pins of the tester 2.

Furthermore, a macro language, into which the commands for controlling the I2C interface are macronized, can be utilized for controlling the I2C controller element mounted on the side of the tester 2 or controlling the drive signals of the tester pins. The tester 2 implements the test of, e.g., the I2C component according to the test program of the macro language corresponding to the I2C control. For instance, the tester 2 sets the I2C-MPX (multiplexer) and controls the target I2C component connected to the I2C-MPX, thus implementing the test of the I2C component.

In FIG. 2, the circuit of the I2C interface can be exemplified by the wire of a broken line, which is connected to the I2C-MPX. The circuit information of the I2C interface exists as, e.g., the information of the net list. An operation of the I2C component is, however, nothing but information of an individual data sheet and is an operation of the component that is absolutely unknown to the JTAG test generator. The JTAG test generator cannot therefore automatically generate the test program of the circuits including the I2C component. Such being the case, in the present comparative example, the developer of the test program for the printed circuit board 9 including the components such as the I2C components other than the JTAG components, devises a test plan by studying the circuit diagram, reading the connecting relation as in FIG. 2 and thoroughly reading the data sheets of the components such as the I2C components other than the JTAG components. This procedure is given as follows.

The developer of the test program for the printed circuit board 9 creates the test program given as below manually, i.e., by a manual operation. The test program connotes a program using, e.g., the macro commands on the tester 2 which executes the test sequence. Then, the developer of the test program for the printed circuit board 9 implements the following tests by executing the created test program in the tester 2.

(1) With respect to the wire L4 in FIG. 2: A test for reading the signal from the I2C component connected to the connector 11 connecting with the tester 2 by outputting the signal from this connector 11.

(2) With respect to the wire L5 in FIG. 2: A test for reading the signal from the I2C component connecting with the target pin by controlling the I2C-MPX and driving the signal from the target pin of the target I2C component.

(3) With respect to the wire L7 in FIG. 2: A test for checking whether the predetermined data is contained or not by controlling the I2C-MPX and reading the data from the target I2C-ROM.

(4) With respect to the wire L8 in FIG. 2: A test for controlling the I2C-MPX by analyzing a voltage applied to the I2C-ADC (voltage measuring component). In this test, the developer of the test program implements the test as to whether the data (divided voltage) read from the target I2C-ADC falls within an allowable voltage of the component.

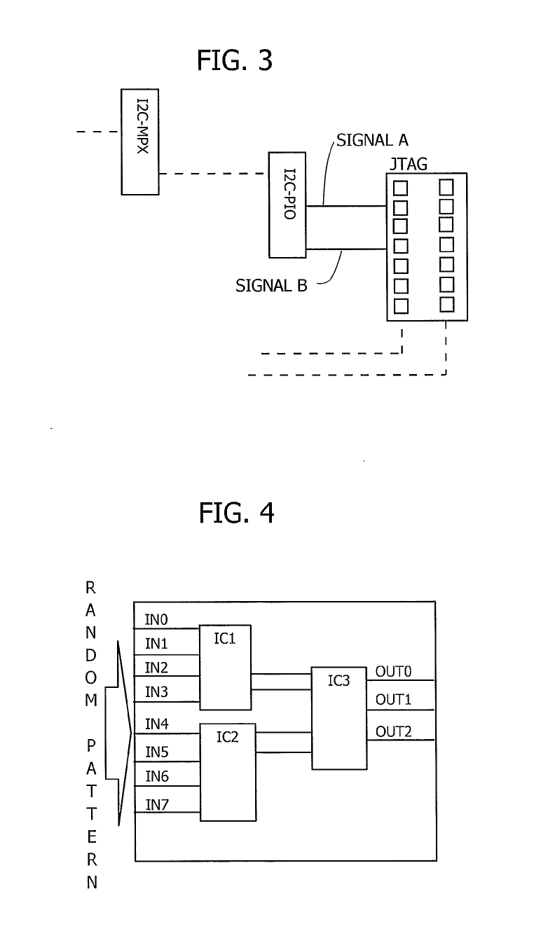

(5) With respect to the wire L6 in FIG. 2: FIG. 3 illustrates a circuit in which the wire L6 portion in FIG. 2 is enlarged. In FIG. 3, the I2C-PIO is controlled via one of the channels of the I2C-MPX. The I/O ports of the I2C-PIO are connected to the JTAG component.

Normally the JTAG test generator is used for generating the test program of the JTAG component. As for the configuration as in FIG. 3, the developer (s) of the test program makes the use of, e.g., a function of a cluster test of the JTAG test generator. The JTAG test generator, which provides the function of the cluster test, is called a cluster test generator.

The cluster test is defined as a function of blackboxing the unknown component and implementing the test in the circuit including the JTAG component. In the cluster test, the unknown component is blackboxed by designating the bit string that is input to the input pin and the bit string that is output from the output pin. The JTAG test generator accepts the unknown component connected to the JTAG component as the blackboxed component. Then, the JTAG test generator generates the test program for the circuit in which the JTAG component and the blackboxed component other than the JTAG component exist in mixture.

For instance, in the example of FIG. 3, the developer of the test program reads the circuit diagram and recognizes that the signals A, B correspond to the wires between the I2C component and the JTAG component, and these wires are test-enabled portions. Next, a JTAG signal pattern received by the pins of the JTAG component is defined by the signals A, B. The JTAG signal pattern is an I/O bit string in the JTAG component, which takes account of, e.g., the open-circuit failure of the wire between the I2C-PIO in FIG. 2 and the JTAG and the short-circuit between the wires. Next, the developer of the test program defines an I2C-MPX control command chain and an I2C-PIO command chain for outputting the thus-defined JTAG signal pattern to the JTAG component from the programmable output port by controlling the I2C-PIO via the I2C-MPX with respect to each JTAG signal pattern.

The thus-defined JTAG signal pattern and the I2C-MPX control command chain and the I2C-PIO command chain, which serve to output the JTAG signal pattern, are given to the JTAG cluster test generator. The cluster test generator converts the given JTAG signal pattern into the JTAG control sequence. Then, the cluster test generator generates the test program of the tester 2 that receives the signals output from the I2C-PIO in FIG. 2 via the JTAG component and checks the received signals.

The procedure of the comparative example 1 discussed above has, however, the following problems.

(1) The automatic generation of the test program not being sufficient: The test program of the portion ranging from the wire L4 to the wire L8 in FIG. 2 is manually generated by the developer of the test program and is therefore disabled from being automatically generated. To summarize the generation method in the comparative example 1, the developer of the test program recognizes the I2C component by analyzing the circuit diagram and grasps which component the recognized I2C component is connected to. Moreover, the developer of the test program recognizes a connection tree extending from an external connector to the target I2C component via the I2C-MPX in order to examine the paths of the I2C control signals. Next, the developer of the test program generates the test program for running the I2C component by making use of the macro language and controlling the I2C-MPX for operating the focused I2C component. For attaining this, the developer of the test program is required to examine the data sheets and understand how to run each I2C component. As described above, if the automatic generation of the test program is insufficient, a period of the time for the development rises. Further, development efficiency and quality acceptability of the test program depend on a skill of the developer.

(2) Difficulty of troubleshooting the failure position: The test program generated in the procedure in the comparative example 1 is provided for determining the quality acceptability. Accordingly, the quality acceptability can be determined by executing the test program, however, it is difficult to diagnose the failure, e.g., to troubleshoot the portion of the failure. Namely, in the test program in the comparative example 1, a message saying that the expected value is different from a read value in reading of the I2C component is output at, e.g., an N-th step of the test pattern. A person in charge of the repair analyzes the test pattern on the basis of such a message of the test program. To be specific, the person in charge of the repair conducts, based on the test program and the circuit diagram, an operation such as analyzing the signals between the components and logically detecting the open-circuit failure between the pins and the short-circuit failure therebetween. Accordingly, a task of improving the time-consuming operation of and the load on the person in charge of the repair still remains in the comparative example 1.

### Comparative Example 2

FIG. 4 is a diagram illustrating how the test program is generated by simulation according to a comparative example 2. FIG. 4 depicts a printed circuit board on which three components such as IC1, IC2 and IC3 are connected. FIG. 4 illustrates inputs IN0-1N3 as input signals to the IC1 and input signals IN4-IN7 to the IC2. Further, FIG. 4 depicts output signals OUT0-OUT2 as output signals from the IC3.

The test pattern is generated by the simulation as follows. The following are items of data used for the simulation.

First data are of the net list of the printed circuit board. Second data are of all operation models of the mounted components. The operation model of the mounted component is defined as data described in a hardware specification descriptive language such as a VHDL (VHSIC (Very High Speed Integrated Circuits) Hardware Description Language) or Verlog, which normally represents an operation of an I/O relation between the mounted components.

A. The procedure of generating the test program is given as below. Herein, for instance, the information processing apparatus 1 performing the simulation generates the test program.

(A1) The information processing apparatus 1 generates the test pattern in which a random pattern is applied to the input pins of the printed circuit board.

(A2) The information processing apparatus 1 calculates levels of the output pins by performing a calculation of an operation model formula from levels of the input pins of the respective components in the individual steps of the test pattern.

(A3) As a result of the operations described above, levels of the input pins of a next stage IC, e.g., IC3 in FIG. 4 are determined. Then, the information processing apparatus 1 obtains the levels of the output pins by performing the calculation of the operation model formula of the component at the next stage. Thus, the information processing apparatus 1 sequentially obtains the levels of the output pins of all the pins.

(A4) The information processing apparatus 1 executes the procedures A2-A3 at all the steps of the random pattern.

B. A method of performing the test based on failure simulation and an evaluation method are given as follows.

(B1) The net list is created, in which the respective nodes are dropped one by one to GND (ground potential) in order to simulate the failure. The information processing apparatus 1 carried out the simulation described above. The information processing apparatus 1 checks through the simulation the outputs of the printed circuit board, e.g., checks whether the result of the OUT0-2 is different from when a good-quality product is provided or not in the case of FIG. 4. If the result of the OUT0-2 is different from when the good-quality product is provided in the net with the failure being simulated, the information processing apparatus 1 determines that the random pattern is capable of detecting the failure.

(B2) If the failure is not detected, the information processing apparatus 1 changes the random pattern and executes the procedure (B1) once again.

(B3) The information processing apparatus 1 selects the random pattern that detects the failures of as many nodes as possible.

C. The following are problems in the test generation based on the simulation described above.

(C1) There is a tendency to generate a tremendous number of unrealistic test patterns.

(C2) The preparation of the operation models is highly time-consuming because of preparing the operation models of all the components of the printed circuit board.

(C3) The failure cannot be easily analyzed.

### Comparative Example 3

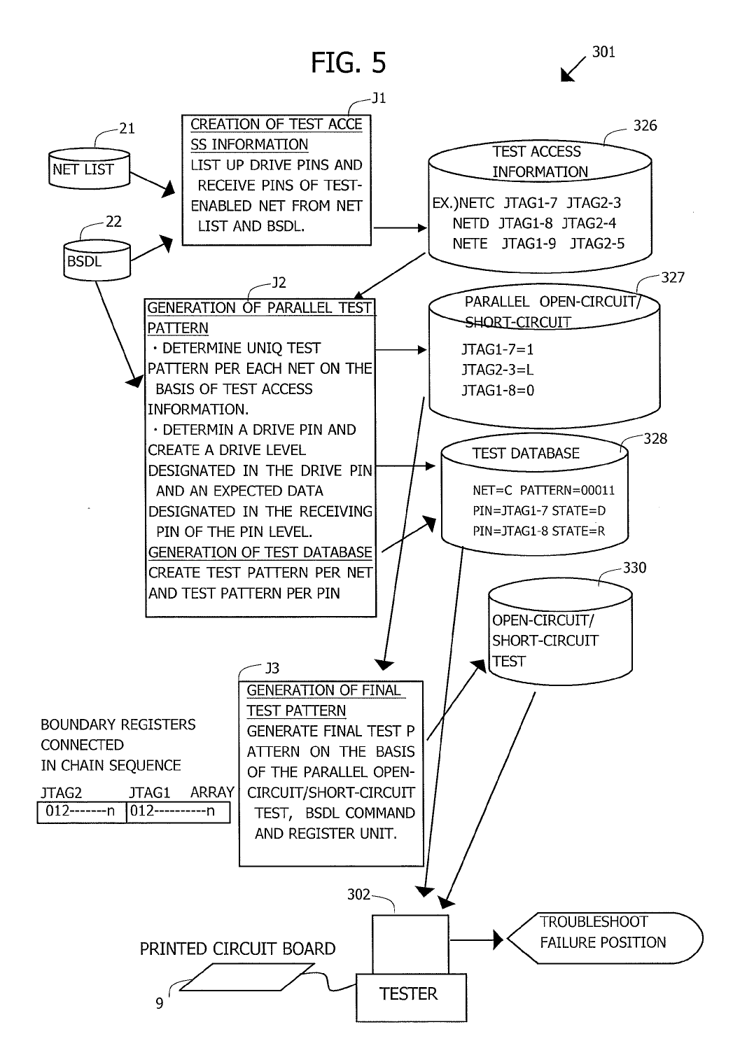

A comparative example 3 will exemplify a procedure of testing the printed circuit board through the JTAG interface. FIG. 5 is a diagram illustrating a process of the JTAG test generator. In FIG. 5, a net list 21, a BSDL file 22, test access information 326, a parallel open-circuit/short-circuit 327, etc are stored in the main memory of the information processing apparatus 1 and in an external storage device. Further, for instance, a test database 328, an open-circuit/short-circuit test 330, etc are stored in, e.g., the external storage device of the tester 302.

To begin with, the JTAG test generator generates the test access information 326 from the net list 21 and the BSDL file 22 (J1). The net list 21 contains information representing the connecting relation between the pins on the printed circuit board and information representing associations between the names of the components on the printed circuit board and the model rating numbers thereof. The net list 21 is one example of a storage unit of the connecting information. The BSDL file 22 is one example of a first operation model storage unit. The information representing the connecting relation is one example of connecting information.

The information representing the connecting relation is exemplified by, e.g., (net identifying information, pin 1, pin 2). The information (net identifying information, pin 1, pin 2) represents that the pin 1 and the pin 2 are connected by the net specified by the net identifying information. Herein, the pin 1, the pin 2, etc are pieces of information for identifying the pins. A format of the pin identifying information is exemplified by, e.g., “component name—pin number”. Furthermore, the information representing the association between the component name and the model rating number is exemplified such as (component name, model rating number). Herein, the “component name” is a name of the component on the circuit diagram of the printed circuit board. On the other hand, the “model rating number” is a model number of the component.

The BSDL file 22 has a definition of the associated relation between the pins of the JTAG component and the internal boundary cells connected to these pins and an I/O definition of the pins. The boundary cells of the JTAG component can be said to be a register group disposed between the pins of the JTAG component and the internal core logic. The boundary cells are serially connected and function as shift registers. The test pattern is input to each boundary cell from a test access port (which is abbreviated to TAP) such as the TDI and TDO and can be shifted. Accordingly, the shift registers with the boundary cells being joined can be set with the test pattern and can output the test pattern to be read. In other words, the boundary cell functions as a probe inserted in between each pin and the internal core logic.

The JTAG test generator recognizes, based on the BSDL file 22, the relation of the shift register on a pin-by-pin basis. Hence, the JTAG test generator recognizes the sequence in which the set test pattern shifts from the TDI on the pin-by-pin basis.

The test access information 326 is exemplified as an aggregation of the nets including drive pins for transmitting the signals and receiving pins for receiving the signals in the nets on the test target printed circuit board. The net including the drive pins and the receiving pins can be said to be a test-enabled net. Accordingly, the JTAG test generator reads the net list, then specifies whether the pins connected per net are the drive pins or the receiving pins by searching the BSDL file and, if the drive pins and the receiving pins exist at a stage of finishing reading all the connection pins of one net, records the test access information for one net with this net being set as the test-enabled net. This operation is carried out for all the nets, thereby creating the test access information.

Next, the JTAG test generator generates the parallel test pattern 327 (J2). The parallel test pattern 327 is the unique test pattern between the nets, which is acquired by way of the test access information 326. That this, the parallel test pattern 327 is determined as the bit string which differs per net. Then, the parallel test pattern 327 is defined as the information allocated to the drive pin and the receiving pin. A drive level is designated in the drive pin. Furthermore, expected data corresponding to the drive pin is designated in the receiving pin. The expected data connotes the data which can be expected to be observed by the receiving pins when the signals of the test pattern are output to the drive pins.

A reason for determining the unique test pattern per net is that the interference can be detected when the wire is short-circuited. For example, it is predicted that the error of the read value of each of the receiving pins of the short-circuited two nets will not occur in the portion with the expected pattern being the same but will occur in the portion with the expected pattern being different. Accordingly, at the stage where the error occurs in the test, it is specified that short-circuit is caused between the relevant nets. The JTAG test generator sets a target control value on the pin-by-pin basis irrespective of the actual control procedure when generating the parallel test pattern 327. The parallel test pattern 327 is also called a parallel open-circuit/short-circuit test pattern.

Next, the JTAG test generator records the test pattern per net, information on the pins within the net, distinctions between the drive pins and the receiving pins, etc in the test database 328. The test database 328 retains the information enabling the whole test pattern to be recognized per net. The test database 328 is used for, e.g., analyzing the failure, etc.

Subsequently, the JTAG test generator generates a final test pattern (J3). The final test pattern is one example of control information. The JTAG test generator embeds, based on the BSDL, drive levels (bit values, 1/0) of the drive pins and expected values (bit values, H/L), which are set in the parallel test pattern, in corresponding bit positions of the array of the boundary cell images. This array is configured in the sequence of a chain of connected boundary cells and is also what the JTAG components are connected to. The example of FIG. 5 exemplifies the array for storing the boundary cells of two LSIs, i.e., JTAG1 and JTAG2. Values “0” through “n” in this array represent entries corresponding to the boundary cells of each JTAG component. The drive level overflowed from the top when shifting this array is set as a write pattern to the TDI, and this pattern is generated as an expected pattern of reading the expected value from the TDO. The JTAG test generator outputs the final test pattern generated above to an open-circuit/short-circuit test file 330.

The tester 302 reads the open-circuit/short-circuit test file 330, and implements the test. To be specific, the tester 302 inputs the bit string from the TDI of the JTAG interface, and observes the bit string from the TDO while shifting between the connected boundary cells. Then, the tester 302 determines whether the signal coincident with the expected value can be received by the receiving pin or not. Subsequently, the tester 302, as a result of the determination, if the error occurs, troubleshoots a failure position by referring to the test database 328.

### Working Example

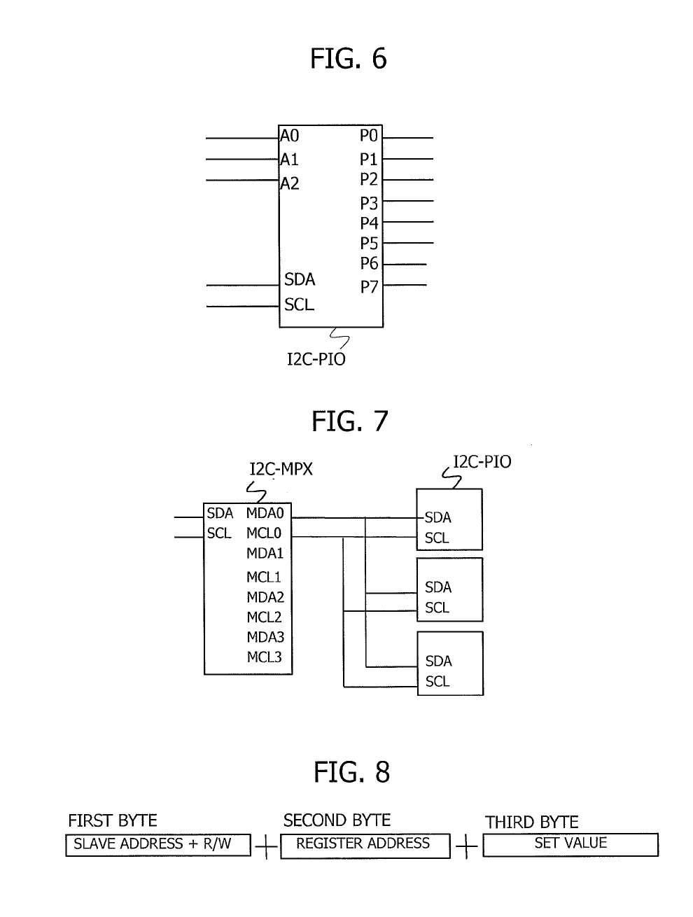

The information processing apparatus 1 according to a working example will be described with reference to the drawings in FIGS. 6 through 9. The present working example will discuss the information processing apparatus 1 that generates the test program for the printed circuit board 9 including the I2C components and the JTAG components.

As described in the comparative example 3, the JTAG test generator generates the test for only the portion related to the JTAG because of the I2C component being unknown. This being the case, in the present working example, the I2C component is expressed in a format recognizable by the test generator. Then, the test generator incorporates the net including the pins of the I2C component into the test access information. Namely, the information processing apparatus 1 in the working example generates an open-circuit/short-circuit test for the circuit including the I2C component and generates a test database thereof.

On the other hand, the tester 2 in the working example implements the test and is further enabled to troubleshoot the failure position. The I2C interface has an ability to control of the components and connections of a tree structure unlike the JTAG. Because of such characteristics of the I2C interface, the working example proposes a way of expressing the internal structure of the printed circuit board 9 including the I2C components, an expression of the tree structure between the pins and a procedure of processing these expressions. Note that the architecture of the system including the printed circuit board 9, the tester 2 and the information processing apparatus 1 is the same as the architecture in FIG. 2.

<Example of Test Target Component>

FIG. 6 is a diagram illustrating I2C-PIO as one of the I2C components included in the test target printed circuit board 9. The I2C-PIO is one example of a second integrated circuit. The printed circuit board 9 is one example of an electronic device. FIG. 6 illustrates an I/O pin of a general type of 8-bits PIO (Program IO). SDA (serial data) and SCL (serial clock) correspond to pins of I2C control signals, i.e., a data pin and a clock pin. SDA/SCL is one example of communication pins.

Further, pins P 0-7 are programmable I/O signal pins. The pins P 0-7 are one example of an input pin and an output pin. Pins A 0-2 are option pins of slave addresses. The I2C component has an IC slave address inside. The I2C component adds values of A 0-2 to the slave addresses retained inside, and calculates the slave address as the circuit.

FIG. 7 illustrates an example of the connection of the I2C component. An I2C bus (SDA/SCL) of the I2C-PIO component is normally connected to I2C-MPX (multiplexer) or an external device. The plurality of I2C components can be connected to a single bus. The plurality of I2C components connected to the single bus is selected by the slave addresses. The I2C-MPX is one example of a third integrated circuit.

The I2C-MPX enlarges the I2C bus. In the I2C-MPX, the SDA/SCL branches the path (two lines) into a plurality of paths called channels. FIG. 7 illustrates a 4-channel configuration. The I2C-MPX also has the slave address. Further, the I2C-MPX has the address pins for changing the slave address. In FIG. 7, MDAn, MCLn (where n=0, 1, 2, 3) represent the pins of multiplexed clock and data.

The I2C component normally has a control register. In the example of the I2C-PIO, there are directional registers (CONF) for determining the inputs and the outputs of the respective pins P 0-7, output registers (OUT) for setting the output levels of the pins and input registers (IN) for taking in a level, e.g., 0/1, of each pin. Moreover, the I2C-MPX has a channel selection register, as a control register, for setting which MDAn/MCLn the I2C bus SDA/SCL is connected to. MDAn/MCLn is one example of a channel communication pin.

FIG. 8 depicts an example of the data designated by the control sequence for controlling the I2C component. FIG. 8 illustrates a byte string transferred and received between the I2C component and the control device for controlling the I2C component. In the control sequence of the I2C component, the data are transferred by use of SDA and SCL. Exemplified herein is the control sequence in which the control device for controlling the I2C component accesses the I2C component by use of the byte string transmitted and received via SDA. This control sequence is a sequence for setting the data in the internal register of the I2C component and is therefore called a setting sequence as well. In the setting sequence, the setting byte string of, e.g., 3 bytes is transmitted via SDA.

A first byte: slave address+R/W bit;

A second byte: register address; and
A third byte: set value in the register.

The control device transmits the slave address for selecting the target component and a R/W bit at the first byte. The I2C component receiving the first byte, if a value of “self-slave-address+address pin” is coincident with the slave address, recognizes that the I2C component itself is selected. Further, it is indicated at the last R/W bit (0-th bit) whether the subsequent transfer is a read access or a write access. For example, “R/W bit=0” indicates the write operation being described. The control device transmits the register address at the second byte. The register address is information for designating the target register which transfers and receives the data. Moreover, the control device transmits, at the third byte, the set value in the register designated at the second byte. What has described so far is a general example of the I2C control sequence.

For instance, in the configuration of FIG. 7, when the channel selection register of I2C-MPX is set, the control device becomes enabled to perform the communications with the I2C-PIO of the selected channel via the I2C-MPX. Accordingly, the control device can set the values in the directional register and the output register of I2C-PIO of the selected channel, and can acquire the values from the input register.

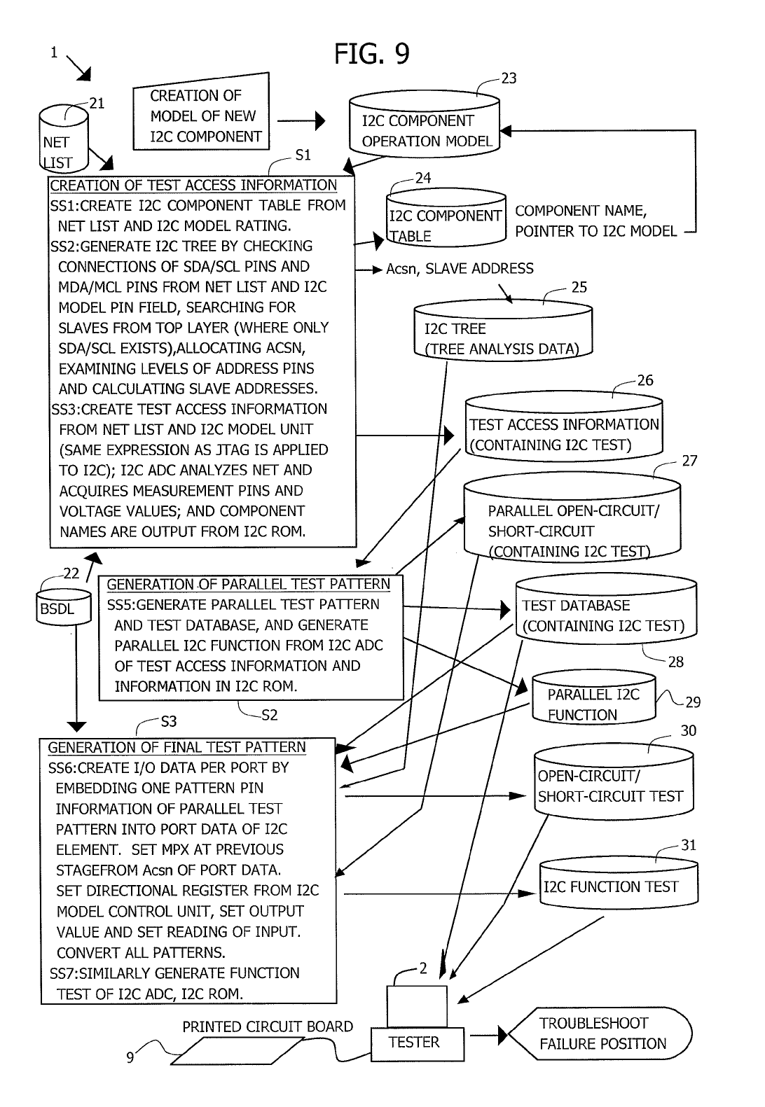

FIG. 9 illustrates a process of generating the test program for the printed circuit board 9 including the I2C component according to the present working example. The system, which provides the function in FIG. 9 to the JTAG test generator discussed in the comparative example 3, can be called a general-purpose test generator. The information processing apparatus 1 executes the computer program deployed in the executable manner in the main memory, thereby functioning as the test generator in the present working example. In FIG. 9, a net list 21, a BSDL file 22, an operation model 23 of the I2C component, an I2C component table 24, an I2C tree 25, test access information 26, a parallel open-circuit/short-circuit 27, a parallel I2C function 29, etc are stored in the external storage device or the main memory of the information processing apparatus 1. Moreover, e.g., a test database 28, an open-circuit/short-circuit test file 30, an I2C function test file 31, etc are stored in the external storage device of the tester 2.

A premise in the present working example is that a user creates the operation model 23 of the I2C component before the test generator executes the processing. The operation model 23 of the I2C component contains a model rating number of the I2C component, a specification of the pin, a slave address, a definition of the register, etc. The operation model 23 of the I2C component can be defined as a text file described in a predetermined format. The operation model 23 of the I2C component is one example of a second operation model storage unit.

Then, the test generator generates the test access information from the net list 21, the operation model 23 of the I2C component and the BSDL file 22 (S1). A procedure of generating the test access information includes an I2C component table creating step (SS1), an I2C tree generation step (SS2) and a test access information output step (SS3). The CPU of the information processing apparatus 1 executes a process of S1 by way of one example of a test access information extracting unit.

Namely, the test generator creates the I2C component table 24 from the net list 21 and the operation model 23 of the I2C component (SS1). The net list 21 contains, similarly to the list explained in the description of components in FIG. 5, the information representing the connecting relation between the pins on the printed circuit board 9, and the information indicating the associations between the names of the components on the printed circuit board 9 and the model rating numbers thereof.

The I2C component table 24 contains the names of the components on the printed circuit board 9 and pointers to the operation model 23 of the I2C component, which are associated with the component names. In the net (net identifying information, pin identifying information 1, pin identifying information 2) in the net list 21, the pin identifying information is defined by, e.g., a combination of “component name—pin number”. Accordingly, the test generator can acquire the names of the components on the printed circuit board 9 from the net list 21. The test generator recognizes the name of the component on the printed circuit board 9 through the net list 21 and searches, based on the model rating number, for the operation model 23 of the I2C component. Then, the test generator acquires information of a storage destination into the information within the operation model 23 of the I2C component having the model rating number associated with the component name. Subsequently, the test generator sets the acquired storage destination information as a pointer associated with the component name. The creation of the I2C component table 24 enables the test generator to recognize the I2C component on the printed circuit board 9 and an internal structure of the I2C component. Hence, the test generator can acquire the interface specification of the component associated with the component name of the net in the net list 21.

Further, the test generator generates the I2C tree (SS2). The I2C tree 25 is information that describes the connecting relations between the pins of the I2C components on the printed circuit board 9 by a tree structure.

In the generation of the I2C tree 25, the test generator checks the connections of SDA/SCL pins and MDA/MCL pins from the net list 21 and the operation model 23 of the I2C component. Then, the test generator establishes a TOP layer (where only SDA/SCL exists) that is the highest layer in a hierarchy of the connecting relations. Subsequently, the test generator searches for the pin connected to a layer lower than the TOP layer. Then, Acsn (access number) is allocated to the searched pin. The Acsn is information indicating the connecting relation of the I2C bus. Acsn is, e.g., in the single net, so enumerated as to be paired with a channel number of a host component and the identifying information representing a connecting destination of a wired connection in which a slave component is connected to a channel specified by the channel number of the host component. Acsn is what sequentially enumerates the destinations of the wired connection between the channel of the host component and the immediate slave component thereunder and becomes the basic information of the tree structure.

Furthermore, the test generator checks a signal level (1/0) of the address pin for determining the slave address as well as generating the I2C tree 25. Then, the test generator calculates the slave address, on the printed circuit board 9, of the I2C component from the internal slave address of the I2C component and from the signal level of the address pin, and writes the calculated address to the I2C tree 25 as a piece of tree analysis data. It does not, however, mean that the storage destination of the slave address of the I2C component is limited to the I2C tree 25. In short, it may be sufficient for the slave address to be stored in the way of being associated with the component name of the I2C component. Accordingly, for instance, the test generator may store the slave address in the I2C component table 24.

Moreover, the test generator generates the test access information 26 from the net list 21 and from the operation model 23 of the I2C component (SS3). The information processing apparatus 1 serving as the test generator executes the process in S3 by way of an example of a test pattern generating unit. The test generator, when generating the test access information 26, expresses the I2C component in the same way as expressing the JTAG component. Further, the test generator analyzes the net of I2C-ADC, and outputs a measurement pin and a voltage value to the test access information 26. Still further, the test generator outputs the component name of the I2C-ROM etc to the test access information 26.

Next, the test generator generates the parallel test pattern 27 (S2). The parallel test pattern 27 is the same as in the case of FIG. 5 except containing the pattern for the I2C component in addition to the test pattern for the JTAG component. To be specific, the test generator determines the test pattern unique to every acquired net as the test access information 26, and allocates the test pattern to the drive pin and the receiving pin.

Moreover, the test generator records, in the test database 28, the test pattern per net, the information on the pins within the net, distinction between the drive pin and the receiving pin, etc.

Furthermore, the test generator generates the parallel I2C function 29 for checking the functions of the I2C-ADC and the I2C-ROM from the information of the I2C-ADC and the information of the I2C-ROM in the test access information 26. The parallel I2C function 29 contains component characteristics of the I2C-ADC, the I2C-ROM, etc, the expected value of the voltage measurement pin, and so on.

Next, the test generator generates the final test pattern (S3). The final test pattern includes a pattern for an open-circuit/short-circuit test and a pattern for the I2C function test. The final test pattern is one example of control information according to the interface specification. The information processing apparatus 1 serving as the test generator executes the process in S3 by way of one example of a generating unit.

That is, the parallel test pattern is a test pattern per pin, however, the I2C component PIO performs driving or receiving on a port-by-port basis. Note that the port is an aggregation of a plurality of I/O pins of the I2C-PIO and is defined as a unit that can be input and output by one operation. For example, 8-bits pins are aggregated and thus controlled as one port. The test generator, at first, embeds the respective pieces of pin information of the parallel test pattern into relevant bit positions of port data variables corresponding to the PIO ports of the I2C component, and generates the I/O data per port by making implementation for one pattern (SS6). The I/O data per port will hereinafter be termed port data. Then, on the basis of Acsn of the port data of the test target component, the test generator sets, in the connections to the test target component, the I2C-MPXs of the 0-th stage connecting with a connecting point, connected to the outside of the printed circuit board 9, of the edge portion of the printed circuit board 9 up to the stage previous to the test target component. The connecting point to the outside of the printed circuit board 9 is one example of an external connecting point.

Namely, the test generator sets the data (which will hereinafter be referred to as control information) according to the control sequence specified in the operation model 23 of the I2C component. With the setting of this control information, the MPX channel is set. Then, it is feasible to test the test target port from the tester pin at the edge portion of the printed circuit board 9, i.e., feasible to perform driving of the drive pin and making the observation at the receiving pin.

Further, the test generator acquires the information of the directional register from the operation model 23 of the I2C component, and sets the input/output to the directional register. Still further, the test generator sets, e.g., an output value of the output register, and sets reading of the input register. The processes described so far are executed about all the bits of the test pattern. Through the processes described above, the open-circuit/short-circuit test file 30 is generated. For example, the final test pattern of the wires L4-L6 in FIG. 2 is set.

Moreover, the test generator generates the function test file 31 of the I2C-ADC and the I2C-ROM (SS7). For instance, there is set the information for testing the I2C-ADC of the wire L7 or the I2C-ROM of the wire L8 in FIG. 2. The open-circuit/short-circuit test file 30 and the I2C function test file 31 may be any of a test file containing a command chain and a binary file for speeding up the processing, and are exemplified by script files. The I2C-ROM is one example of a fourth integrated circuit.

The tester 2 reads the open-circuit/short-circuit test file 30 and the I2C function test file 31, then translates the file data into bit strings and implements the test. Specifically, the tester 2 supplies the test pattern from the TDI of the JTAG interface, and compares the pattern being output from the TDO with the expected value. Further, with the setting of the I2C component being generated by a dedicated command, the tester 2 translates this setting and controls the I2C controller, thereby making the setting of the I2C-MPX, outputting the drive pattern to the I2C-PIO etc and comparing the signal received by the receiving pin with the expected value. Then, the tester 2, as a result of the determination, if the error occurs, troubleshoots a failure position by referring to the test database 28.

The information processing apparatus 1 according to the present working example executes the processes in this working example on the premise that the operation model 23 of the I2C component is set. That is, the CPU of the information processing apparatus 1 executes as the test generator the computer program on the main memory, and automatically generates the test program including the I2C components. The operation of the I2C component is generated as the test database 28, and hence, similarly to the circuit of the JTAG component, the tester 2 can troubleshoot the open-circuited position and the short-circuited position in a way that explicitly indicates the short-circuited net or the disconnected pins in an error message.

<Specific Example of Test Generator>

The processing of the test generator will hereinafter be specifically described.

<<Processing of Test Generator for Operation Model of I2C Component>>

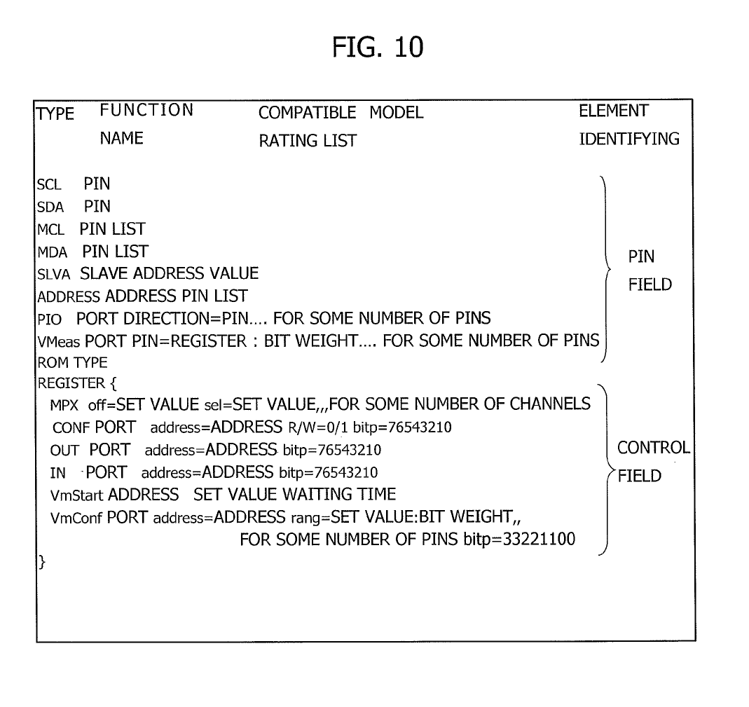

FIG. 10 is a diagram illustrating a structure of the operation model 23 of the I2C component. The test generator recognizes the I2C component from the information of the operation model 23 of the I2C component, and acquires the control method of the I2C component and the interface specification. The test generator acquires, e.g., the model rating number associated with the name of the component on the printed circuit board 9 from the net list 21. Then, the test generator specifies the operation model 23 of the I2C component coincident with the acquired model rating number from the plurality of models. That is, the test generator compares the acquired model rating number with a TYPE line in the operation model 23 of the I2C component. Then, if the comparative result indicates coincidence, the test generator reads the coincident operation model 23 of the I2C component from a data structure of the main memory.

Furthermore, the test generator creates the I2C component table 24 stored with the component name and the pointer to the operation model 23 of the I2C component. Next, the test generator reads a component pin connecting relation field of the net list 21, and, if the readout component name exists in the I2C component table 24 given earlier, the component becomes the I2C component. Moreover, the test generator searches the pin field of the operation model 23 of the I2C component for the pin read from the net list 21. Then, the test generator specifies which pin function defined in the operation model 23 of the I2C component the pin defined in the net list 21 has.

Therefore, the identifying information of the pin defined in the net list 21 may be commonized to the identifying information of the pin in the pin field set in the operation model 23 of the I2C component. There may also, however, be defined an associated relation between the identifying information of the pin defined in the net list 21 and the identifying information of the pin in the pin field set in the operation model 23 of the I2C component. Note that the combination of “component name—pin number” is used as the identifying information of the pin in the following working example. The pin identifying information is, however, referred to simply as the pin number by omitting the “component name—pin number”. Further, it does not mean that the format of the pin identifying information is limited to the “component name—pin number”.

Moreover, the test generator acquires the information of a control field of the operation model 23 of the I2C component. The control field of the operation model 23 of the I2C component contains a description of the control method of the I2C component. The test generator generates the final test pattern according to the information in the control field in the operation model 23 of the I2C component.

<<Definition of Operation Model of I2C Component>>

The operation model 23 of the I2C component will hereinafter be described based on FIG. 10. In FIG. 10, the operation model 23 of the I2C component is defined by commands and parameters. The commands are given such as TYPE, SCL, SDA, MCL, MDA, SLVA, ADDRESS, PIO, VMeas, ROM and REGISTER. Note that the REGISTER command contains definitions of subcommands such as MPX, CONF, OUT, IN and VmStart. Further, as in FIG. 10, the operation model 23 of the I2C component is defined in separation into three fields such as an element identification field, a pin field and a control field. Definition contents defined in the operation model 23 of the I2C component are one example of the interface specification.

The element identification field contains definitions given by the TYPE command. A parameter of the TYPE command is described in a way that connects a function name, model rating with respect to the function name, etc by commas to be shown for each of compatible components.

The pin field contains definitions given by commands of pin nomenclatures, in which pin identifying information of the pin, e.g., a pin number is specified by the parameter. For instance, the SCL command and the SDA command define the pin number of the clock and the pin number of the data of the I2C bus. Moreover, the MCL command and the MDA command specify the pin number of the multiplexed data and the pin number of the multiplexed clock. More specifically, the pin numbers are so enumerated corresponding to the number of channels in the sequence of the channels as to be connected by commas. It is to be noted that the channel, i.e., the pin is selected based according to the designation in the channel selection register. The designation in the channel selection register is one example of a selective designation. The MCL command and the MDA command are one example of selective designation information.

The SLVA command designates a slave address possessed inside by the I2C component. The ADDRESS command defines an address pin used for calculating the slave address. The parameters of the ADDRESS command designate, e.g., a pin count and a pin number from the high-order (top). Character strings of the SLVA command and the ADDRESS command are one example of address calculation information.

The PIO command defines a PIO pin. A port is, however, defined in every predetermined number of PIO pins. Then, in the example of FIG. 10, a port name and a string of pin numbers belonging to the port specified by the port name are designated. The string of pin numbers is specifically a string of “direction=pin number”. The “direction” involves describing identifiers that specify “input”, “output” and “two-way” and describing the pin number after “=”. The description is made by connecting these elements to a degree corresponding to the pin count by commas.

The VMeas command defines a voltage measurement pin. The port name is described, and a voltage read register address and a bit weight with respect to the pin number are described. These elements are described to the degree corresponding to the pin count.

The ROM command describes a type of the ROM. The “type” is typified such that the address designation of the ROM data is 1 byte or 2 bytes, and so on.

The REGISTER command declares a start of describing the structure of the register. The MPX subcommand defines set value of a channel selection register to select a multiplexer pin (channel) of the I2C interface. A set value of “All channel-off” is described by “off”. Further, a selection value for selecting each channel from the high-order of the channel is described by “sel=”. The channel selection value designated by “sel=” is one example of selective designation information.

The CONF subcommand defines a PIO signal direction setting register. The port name is described, and the register address thereof is next described. A set value of read/write is defined after “R/W=”. An example is given such as R/W=1/0. An inter-register bit position of each pin is defined by “bitp=”. In the example of FIG. 10, the definition is that the bit position is given by bitp=76543210, the pin P7 of the PIO corresponds to a most significant bit (MSB), and P0 corresponds to a least significant bit (LSB).

The OUT subcommand defines the output register of the PIO. The port name is described, and the register address thereof is next described. An inter-register bit position of each pin is defined by “bitp=”. The output register is a register which sets an output level (1/0) of each of the pins P7-P0.

The IN subcommand defines an input register of the PIO. The port name is described, and the register address thereof is next described. An inter-register bit position of each pin is defined by “bitp=”. The input register is a register which takes in the level (1/0) of each pin. The I2C component reads the data from the pin with “R” being set by the direction register, and stores the data in the input register. Furthermore, the I2C component outputs the data of the output register to the pin with “W” being set.

The VmStart subcommand defines a voltage measurement start procedure. The register address of the setting register is described. Next, the set value is described. Note that the set values are described in the way of being connected by the commas in the case of defining the setting sequence containing the plurality of set values. Next, a period of measurement waiting time is described. The voltage measurement is started normally in common among all the voltage measurement pins, and therefore the port name is omitted.

The VmConf subcommand defines the designation especially for a range designation enabled component with respect to the voltage measurement in the components undergoing the designation of the voltage measurement pin designated by the VMeas command. There are described, for instance, the register address in which the range data is set, a range to be defined, a bit weight corresponding to the range, and so on.

As described above, the pin field of the operation model 23 of the I2C component contains definitions of the pin number/direction, and the slave address value and the address pin of the component. The slave address value and the address pin of the component are defined, and hence the test generator can acquire calculation information of the slave address from the operation model 23 of the I2C component. The definitions of the slave address value and the address pin of the component are one example of address calculation information. Given further in the control field are a register specification, a register address, an associated relation between the register and the pin, Input/output directions, an output level and an input reading method. Accordingly, the operation model 23 of the I2C component can include one example of the interface specification of the I2C component.

<<Example of I2C Tree Generation Process>>

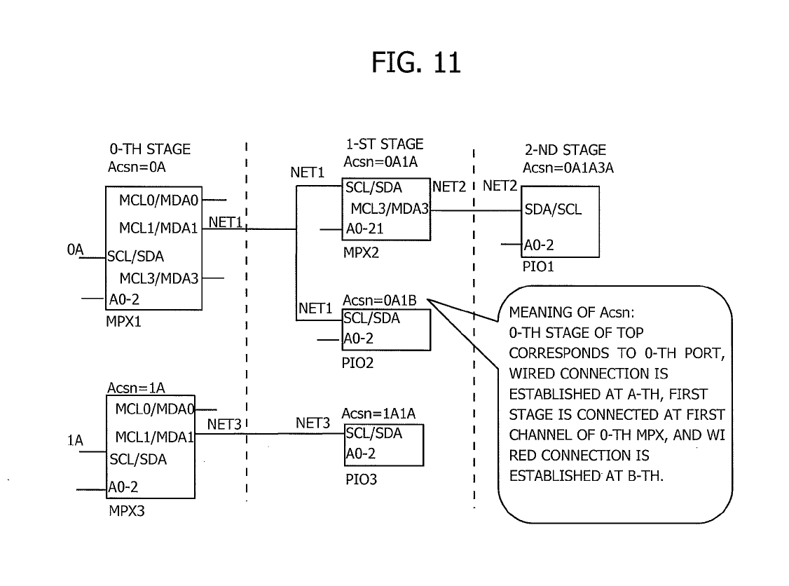

FIG. 11 illustrates the connections among the I2C component. The I2C components are connected by a tree structure illustrated as in FIG. 11. The I2C tree 25 in FIG. 9 is information for defining the connecting relation between the I2C components as in FIG. 11. A procedure of generating the I2C tree 25 will hereinafter be exemplified in accordance with FIG. 11. The present working example proposes a notation called Acsn (Access No.) by way of a simple method for expressing the tree.

Acsn=nwnwnwnwnw

n: “n” notates the channel number, however, information for identifying the channel may be adopted as a substitute for the channel number. The channel number indicates a channel of the tester 2, i.e., a tester channel at a 0-th stage, and also indicates a channel of the MPX from a first stage onward.

w: “w” notates the information for identifying a wired connection, and characters are allocated to “w” in the sequence of A, B and C in the present working example.

In the definition of Acsn, “n” and “w” are described as a pair, and two characters from the left represent a state of the 0-th stage, i.e., a connecting state of the highest-order component of the connector 31. Further, the next two characters represent a state of the first stage, i.e., a connecting state of the highest-order component to the next component. Herein, the connecting state to the next component is expressed by, e.g., a connection channel to the component located in a subordinate position and a wired connection number. Moreover, the next two characters represent the connection channel to the component located in a further subordinate position and the wired connection number. The rule described above facilitates specifying the connection channel of the component being focused and the component at the previous stage. For example, Acsn of the component at the stage previous to the component being focused can be obtained simply by deleting the two characters representing the connecting state to the component located in the subordinate position from the component being focused. The I2C tree generation process involves executing the generation of Acsn of each component, the calculation of the slave address used for accessing the component on the I2C bus and the generation of the visualized I2C tree structure effective in debugging.

An Acsn calculation process will hereinafter be described by taking a circuit diagram in FIG. 11 for example. The test generator acquires the model rating of the component on the printed circuit board 9 from an association field between the component name and the model rating in the net list 21. Then, the test generator specifies the information in the operation model 23 of the I2C component, which is associated with the acquired model rating, from the element recognition field in the operation model 23 of the I2C component. Subsequently, the test generator creates the I2C component table 24 by setting the pointer to the information, specified as the component name, in the operation model 23 of the I2C component.

Next, the test generator reads the pin number of the pin from the component pin connecting relation defined in the net list 21. Furthermore, the test generator, if the component name of the component having this pin exists in the I2C component table 24, recognizes the component as the I2C component. Then, the test generator searches for the pin number of the component pin from the pin field in the operation model 23 of the I2C component, which is associated with the model rating. Subsequently, the test generator, if the searched pin number is coincident with any of the SCL/SDA pin number and the MCLn/MDAn pin number, records the net name of the component pin that is described in the net list 21 on the main memory.

At the stage of finishing reading all the nets, there are recorded the net names of the SCL/SDA pin and the MCLn/MDAn pin to which the I2C components are connected. In this recording, the pins with the same net name being described are connected, and hence the test generator recognizes the connecting relation between the pins on the I2C bus. A portion where MCLn/MDAn pin is not connected to the SCL/SDA pin corresponds to the uppermost stage (0-th stage), i.e., the TOP layer. In the example of FIG. 11, the SCL/SDA of the MPX1 and the SCL/SDA of the MPX3 correspond to the 0-th stage. Then, the test generator attaches, at first, the Acsn (Access No.) to the TOP layer. In FIG. 11, Acsn=0A, and Acsn=1A. The first digit of the first Acsn is a number for identifying the connector serving as the interface of the printed circuit board 9, e.g., the channel (which will hereinafter be referred to as a tester channel) of the connector of the tester 2. Further, an alphabetic letter of the second digit is the number of the wired connection to the line connected to the tester channel, in which the alphabetic letters are attached in the sequence of A, B and C.

Subsequently, the test generator continues to search for the channels downward sequentially from the first channel (MCLn/MDAn) of the TOP component and thus can generate the I2C tree 25 by creating all the access numbers Acsn. The test generator can recognize, from this Acsn, the MPX connected to the stage previous to the focused I2C component and the connection channel. For example, “Acsn=0A1B” implies that “the connection of the component of the TOP layer (0-th stage) is such as, the wired connection of the 0-th tester channel is established at A-th, further, the component at the first stage is connected to the first channel of the MPX of the component at the 0-th stage, and the wired connection is established at B-th”. The test generator can recognize the MPX setting method from the Acsn described above.

Moreover, the test generator searches for the net information of the address pin (A0-2) in the operation model 23 of the I2C component at the stage of reading the net list 21. Then, the test generator analyzes the level (1/0) of the address pin from the connecting relation indicating whether connected to GND or the power source via a resistance. Subsequently, the test generator adds the set value in the recognized address pin and the internal slave address of the I2C component, which is obtained from the operation model 23 of the I2C component, thus calculating the slave address, on the printed circuit board 9, of the I2C circuit component.

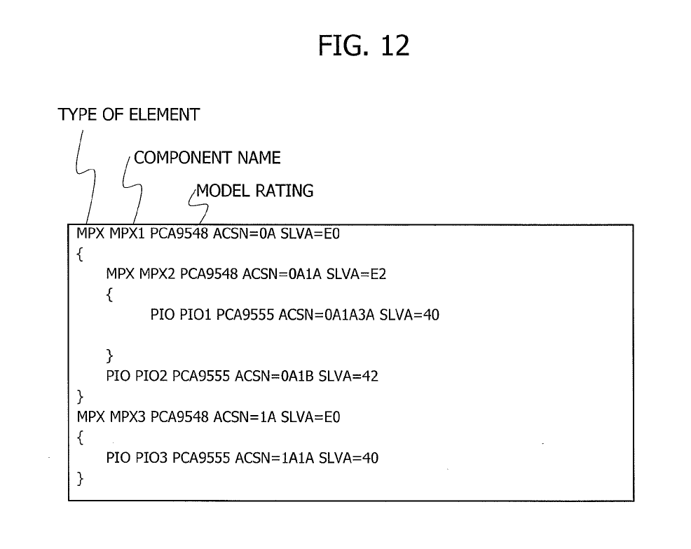

FIG. 12 illustrates an output image of the I2C tree 25. As in FIG. 12, a format is such that the type of the component (element), the component name, the model rating, the Acsn and the slave address (SLVA) are enumerated from the top (0-th stage) of the I2C tree 25. Further, definitions of the component at the next stage are enumerated in an internal area delimited by curly brackets “{ }” next to the definitions of the high-order component. To be specific, in the example of FIG. 11, the connecting relation of the component name MPX1 of the highest-order component is recorded, first. Then, the connecting relation with the pin of the component name MPX2 of the next stage component is defined in the line next to the component name MPX1, and the connecting relation with the pin of the component having the component name PIO1 of the next stage component is defined in the further next line. Then, when the tree related to the component name MPX1 of the highest-order component is terminated, the connecting relation of the component name MPX3 of the highest-order component is further recorded.

<<Processing Flow of Generating I2C Tree>>

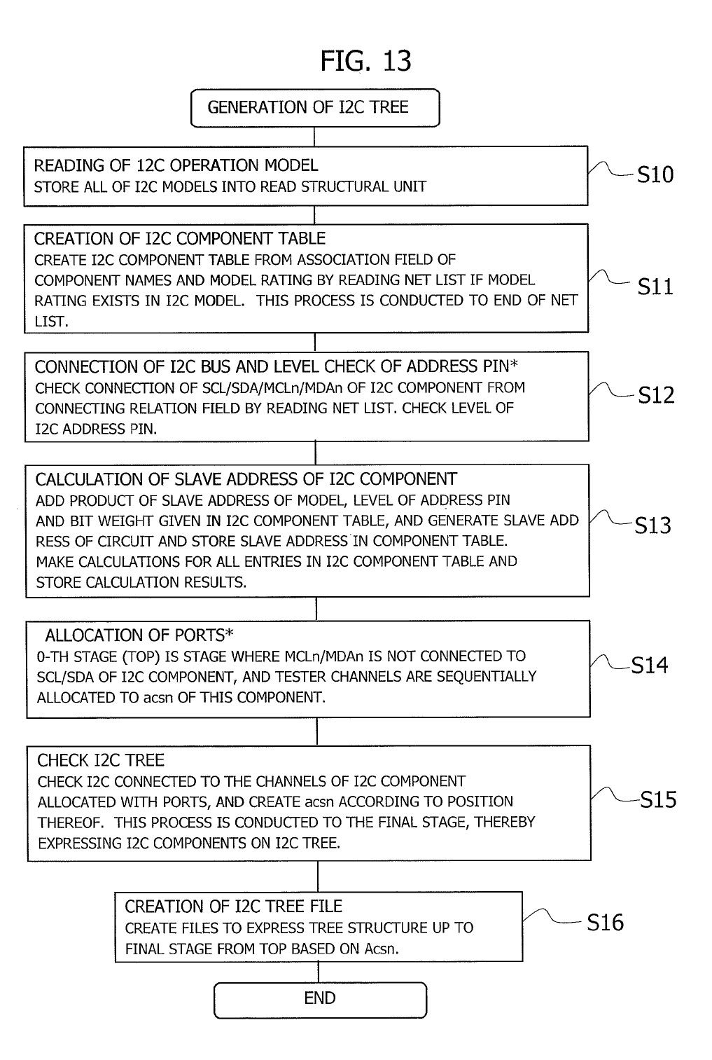

FIG. 13 illustrates a processing flow of generating the I2C tree. In this process, the test generator reads the already-defined operation model 23 of the I2C component and stores the operation model 23 in a corresponding data structure on the main memory (S10).

Next, the test generator creates the I2C component table 24 (S11). That is, the test generator acquires the model rating associated with the component name from the association field between the component name and the model rating by reading the net list 21. Then, the test generator, if the model rating exists in the I2C model, creates the I2C component table 24. Namely, the test generator records the pointer to the I2C model corresponding to this component name. Then, the test generator executes the process described above for all the component names defined in the net list 21.

Next, the test generator checks a state of the I2C bus connection and the level of the address pin (S12). That is, the test generator checks the connections of SCL/SDA/MCLn/MDAn (“n” is the channel number) of the I2C component from the connecting relation field by reading the net list 21. To be specific, if the pins of the connected I2C component are SCL/SDA/MCLn/MDAn, the test generator makes a note of the nets of these pins and, when finishing reading 1 net, makes the note of there being a source if the MCLn/MDAn pin is connected to the SCL/SDA pin. Moreover, the test generator checks the level of the address pin of the I2C component at the stage of examining the connection. That is, in the case of getting coincident with the address pin of the I2C component, if this net is the net of the power source or GND, the level (logical value) of this pin is, if connected otherwise to the resistance, taken into the note depending on the power source or GND by examining the net of the pin on the opposite side.

Next, the test generator calculates the slave address of the I2C component. That is, the test generator generates the slave addresses of the I2C components on the printed circuit board 9 by adding products of the slave addresses, indicated by the I2C component table 24, in the operation model 23 of the I2C component, the levels of the respective address pins and the bit weights (S13). The information processing apparatus 1 serving as the test generator executes the process in S13 by way of one example of an address calculating unit. Then, the test generator stores the thus-calculated slave addresses in, e.g., the I2C component table 24.

Next, the test generator allocates the tester channels (S14). The test generator determines, based on the connections of SCL/SDA/MCLn/MDAn of the I2C component, the connecting relation between the SCL/SDA and the MCLn/MDAn. Then, the test generator determines that the component with the source not existing in SCL/SDA and with MCLn/MDAn not being connected exists at the 0-th stage (TOP). Then, the test generator allocates the tester channels to the component determined to exist at the 0-th stage (TOP) sequentially from “0”.

Subsequently, the test generator examines the I2C tree (S15). Namely, the test generator examines the I2C components connected to the channels of the I2C components allocated with the tester channels. Then, the test generator generates Acsn according to the connecting position, i.e., the channel number of the I2C component as a source of the connection and the wired connection number of the wired connection linking thereto. For instance, the test generators sets the alphabetic letters such as A, B and C in the respective wired connections sequentially from the first wired connection, and thus allocates the wired connection numbers to the I2C components defined as the destinations of the wired connections. The test generator generates Acsn of all the connected I2C components by executing the processes described above for the I2C components ranging from the I2C component allocated with the tester channel down to the final stage I2C component connected thereto, and stores Acsn in, e.g., the I2C component table.

Then, the test generator can recognize, based on Acsn, the tree structure starting from the TOP down to the final stage, and generates the I2C tree 25 as the file data for checking on the basis of this tree structure (S16).

<<Test Access Information Generation Process>>

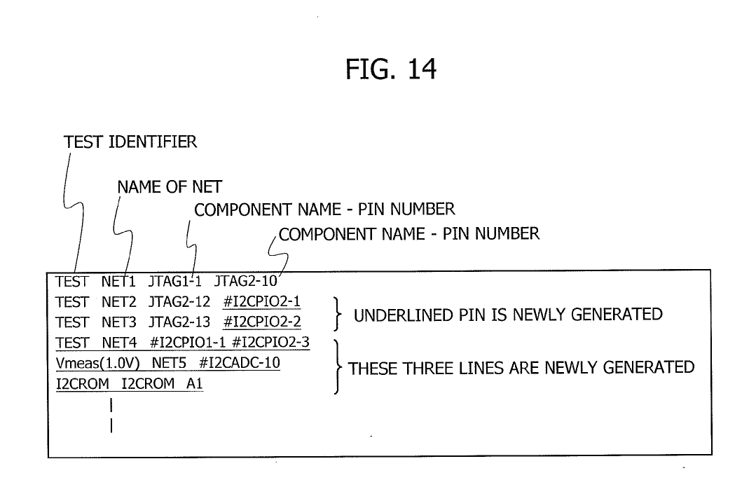

FIG. 14 illustrates an output image of the test access information. The test access information is the information in which to enumerate the test-enabled nets each normally having the drive pins for driving the signals and the receiving pins (including the tester pin) for receiving the signals. In the example of FIG. 14, a test identifier, a net name, “component-pin number” and “component-pin number” are illustratively given in each line. The test identifier can be exemplified such as TEST, VMeas and I2C-ROM. The TEST represents a designation of a connection test between the normal pins. The net name and the “component-pin number” undergoing the test in this net are designated as a pair in the line with the TEST being designated. As in FIG. 14, the test generator acquires, as the test access information, e.g., the pin 12 of the JTAG2 defined as the JTAG component and the pin 1 of the I2C-PIO2 defined as the I2C component.

Further, the VMeas represents a designation of a voltage measurement test for the I2C-ADC. In the example of FIG. 14, the designation is that the voltage value is read from the pin 10 of the I2C-ADC defined as the I2C component in the NET5. Note that a value given in parentheses attached to the VMeas designates a voltage value applied to the test target pin. Accordingly, the tester 2 reads the data from the pin named I2C-ADC-10 of the relevant net, e.g., the NET5 in FIG. 14, and calculates the voltage value according to the bit weight. Then, the tester 2 determines whether the calculated voltage value is coincident with the value in the parentheses of the VMeas or not.

Further, the I2C-ROM represents a designation of the read test with respect to the ROM. The read test with respect to the ROM involves designating the address type.

The JTAG test generator extracts the JTAG pin as the component pin. The test generator in the present working example can extract the drive pin and the receiving pin of the I2C component similarly to the pin of the JTAG component by making use of the operation model 23 of the I2C component and the I2C component table (which will hereinafter be simply referred to as the I2C model including the I2C operation mode). Accordingly, the test generator can generate the subsequent test program on the printed circuit board 9 including the I2C components. Moreover, the present test generator generates a voltage measurement component and a ROM test program as well, which were not generated by the JTAG test generator.

The present test generator reads the pin connecting relation in the net list 21 and refers to the JTAG component table, thereby determining from the component name of the pin per net whether the pin exists or not. Herein, the component table of the JTAG components is information stored with the component names and the pointers to the BSDL data. If the determination target component name exists in the TAG component table, the test generator records the pin and the I/O information in the array. The pin I/O information of the JTAG component is defined in the BSDL 22. Further, if the pin is the pin of the connector of the tester 2, this pin and the I/O information are recorded in the array.

Whereas if the determination target component name does not exist in the JTAG component table, the test generator determines whether or not the determination target (“component name—pin number”) component name exists in the I2C component table 24. Then, if the component name exists in the I2C component table 24 and if the pin number is coincident with the pin number of the PIO pin in the pin field of the operation model 23 of the I2C component, the pin and the I/O information are recorded in the array. The pin I/O information of the I2C component is defined in the operation model 23 of the I2C component.

The test generator, if there are the drive pin and the receiving pin at the stage of finishing the read of one net, determines that this net can be tested. Thereupon, the test generator stores, in the main memory, the test access information 26 with an image as illustrated in FIG. 14 from the information recorded in the array. Note that FIG. 14 illustrates the test access information 26 in a text format, however, it does not mean that the format of the test access information 26 is limited to the text format.

Furthermore, if the pin read herein is deemed, from the I2C component table 24, to be coincident with the pin of the VMeas character string in the pin field of the operation model 23 of the I2C component, this pin is the voltage measurement pin (I2C-ADC). Thereupon, the test generator contrives to express the voltage measurement as a command, then reads the voltage applied to the measurement portion from the net list 21, calculates the voltage value of this net and suffixes the voltage value to the identifier.

Moreover, if the component name of the pin, which is designated in the I2C component table 24, is the ROM in the operation model 23 of the I2C component, the test generator recognizes the I2C-ROM component. The I2C-ROM component is not the component on the net basis. In the present working example, however, the test generator lists up the component names and the slave addresses of the circuits on the basis of the I2C tree.

<<Generation of Parallel Test Pattern>>

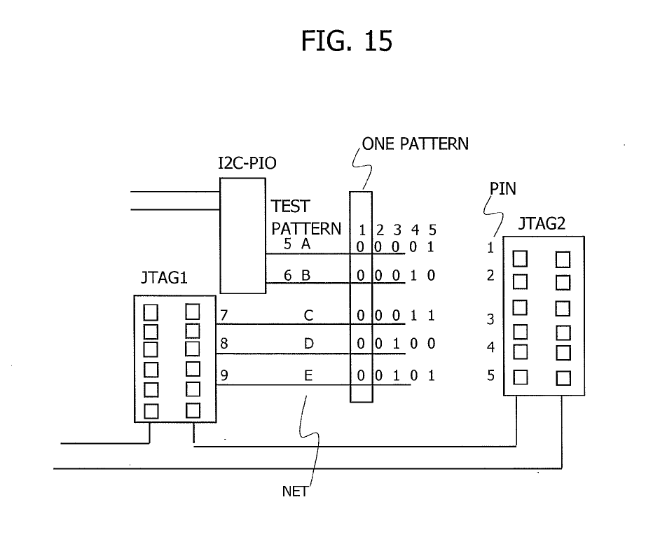

FIG. 15 illustrates the circuit in which the parallel test pattern is generated. The parallel test pattern is the information not taking the control procedure of the tester 2 into consideration but containing the settings of the target value to the drive pin and the expected value in the receiving pin. In the present working example, the parallel test pattern is exemplified by the open-circuit/short-circuit test and the I2C function test.

The test generator outputs the test-enabled net to the test access information 26 as in FIG. 14. Further, the test generator determines the test pattern for the test-enabled net in the test access information 26.

The test generator, in the short-circuit test, allocates the unique test pattern to each of the target net as in FIG. 15. As the test patterns, for instance, “00001” is allocated to the net marked with a symbol “A”, and “00010” is allocated to the net marked with a symbol “B”. As a result of the allocation, e.g., if the interference occurs between the plurality of receiving pins in any whichever step when short-circuited, the tester 2 can detect the failure.

Further, the open-circuit test involves, when a plurality of drivers exists in the net, switching over the driver and generating the pattern for driving 0/1. If the data of 0/1 driven by the driver cannot be observed by the receiving pin of the net, a disconnection is detected. Herein, the “driver” connotes the pin for sending the data to the net.

For example, “JTAG1-1=1” indicates that the level of the “pin:1” of the “component:JTAG1” is “1”. Further, “JTAG2-10=L” indicates that the expected data of the “pin: 10” as the receiving pin of the JTAG2 is “L”. In the present working example, the expected data of the pin as the receiving pin is indicates by “H” (high electric potential) and “L” (low electric potential).

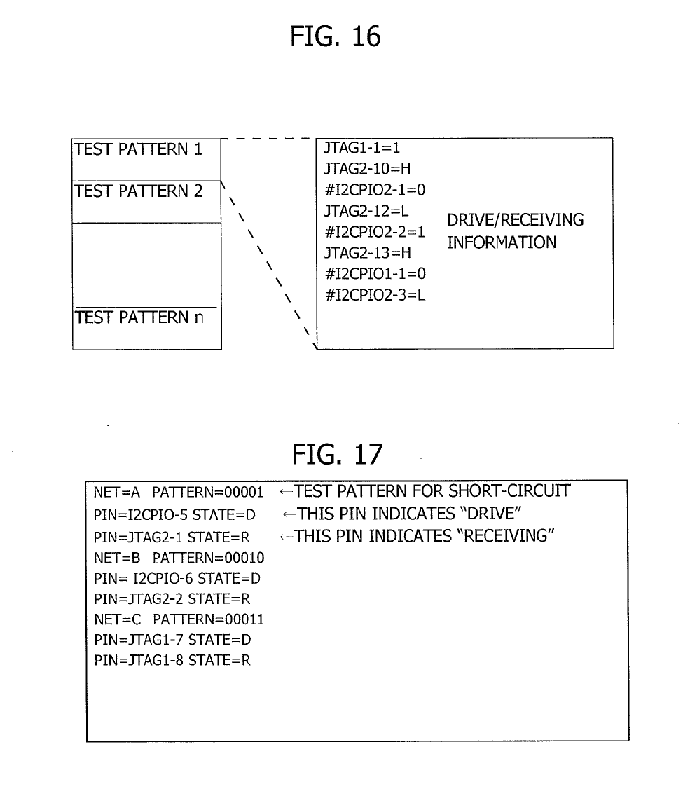

Note that the test pattern in FIG. 16 does not take account of the JTAG and the I2C control sequence and is therefore called a parallel test pattern. Moreover, one pattern of the test pattern corresponds to a pattern for 1 bit of each net, e.g., one pattern is defined as a bit group where the bits are arranged in a vertical direction as surrounded by a frame in FIG. 15.

Furthermore, in the course of setting the parallel test pattern, as in FIG. 17, the test pattern per net and the driving/receiving pattern per pin are generated as the test database 28. The example of FIG. 17 illustrates that a test pattern of NET=A is “00001”, the drive pin is I2C PIO-5, and the receiving pin is JTAG2-1. These pieces of data are used for analyzing the failure as will be done later on.

Through the process described above, the test generator performs processing by referring to the pin I/O information in the pin field of the operation model 23 of the I2C component with respect to the I2C component. Then, the test generator represents the parallel test pattern and the test database 28 similarly to the JTAG pin.

Note that each of the I2C-ADC (voltage measurement component) and the I2C-ROM is a single component or is related to the pin test but not related to the open-circuit/short-circuit test. The test generator, however, with respect to the I2C-ADC (voltage measurement component) and the I2C-ROM, generates the test pattern (chain of commands) as the parallel I2C function test information separately from the open-circuit/short-circuit test on the basis of the test access information 26 and the operation model 23 of the I2C component.

<<Example of Process>>

In FIG. 14, the net with TEST being the identifier of the test in the test access information 26 is an open-circuit/short-circuit test-enabled net. The test generator generates the test pattern for the net with TEST being the test identifier. In FIG. 15, crosswise patterns of each of the nets A-E indicate a series of test patterns. The test patterns are illustrated only between JTAG-JTAG and with respect to JTAG-I2C in FIG. 15 but actually generated for the portions of the wires L1-L6 in FIG. 2. The test for the printed circuit board 9 is implemented in the parallel arrangement of the respective nets, and hence it follows that one line in the vertical direction corresponds to the test pattern (one pattern) at one step.

Next, the test generator generates the driving/receiving information of each pin component on a pattern-by-pattern basis. One pattern is defined as the bit pattern (see the framed portion in FIG. 15) formed by taking out the bits one by one with respect to the respective nets from the test patterns (arranged in the crosswise direction) set for the respective nets in FIG. 15.

FIG. 16 is a diagram illustrating a process of allocating the test pattern to the net for the short-circuit test. In the short-circuit test, the test generator determines the drive pin per net, and generates the drive level of the pin determined as the drive pin as in FIG. 16. In FIG. 16, further, the test generator outputs the receiving pin and the expected value data (level) as in FIG. 16 in order for another receiving pin capable of receiving the signal from the drive pin to read the signal level of the drive pin. In FIG. 16, the open-circuit test involves generating the test pattern so as to drive 1/0 and receive the driven signal by another component pin in a way that sequentially switches over the drivers when a plurality of drivers exists in the net.

With the procedure described above, the test generator generates a combination of the drive pin and the drive level or a combination of the receiving pin and the receiving level on a pattern-by-pattern basis as in FIG. 16. Namely, the value (1 or 0) of the test pattern for the drive pin and the expected value (H or L) in the receiving pin for receiving the signal from this drive pin are enumerated together with the drive pin and the receiving pin.

In the course described above, the test generator acquires the I/O information of the I2C component from the I2C model, and processes the I/O information in the same way as in the case of the JTAG. Further, the test generator, before generating the driving/receiving information of the pin level, generates information of the net names of the pins about the respective bits as port connection information with respect to the respective ports of I2C-PIO. This intends to specify the error net similarly to the JTAG when detecting the failure. Moreover, the test generator generates the test database 28 stored with the series of test patterns for the respective nets and the series of test patterns (in the case of the open-circuit) for the pins in order to analyze the failure in the open-circuit/short-circuit test. The tester 2 comes to recognize the behavior on the whole owing to the test database 28.

FIG. 17 illustrates a structure of the test database 28. As in FIG. 17, the test database 28 contains an enumeration of the test pattern, the drive pin (STATE=D) to which the test pattern is set and the receiving pin (STATE=R) for receiving the signal from the drive pin on the net-by-net basis.

<<Generation of Final Test Pattern>>

The parallel test pattern is the information of the bit string that can be said to be the target value for the driving and receiving pins on the pin basis. Accordingly, the parallel test pattern is not structured as the control information according to the operational specification of the JTAG component or the I2C component. Thereupon, the test generator generates the control information for the JTAG interface and the control information for the I2C interface in order to realize the parallel test pattern. The control information for realizing the parallel test pattern with respect to each net is called a final test pattern. The final test pattern can be generated, e.g., in a script format containing the macro commands etc input to the tester 2.

The test generator allocates the parallel test patterns set in the pins of the JTAG component to the boundary cells, generates the information for shifting to, e.g., the TDI and generates, based on this information, the final test pattern. Moreover, the test generator converts the parallel test patterns set in the pins of the I2C component into the final test pattern. The test generator generates the port data on the port basis of the PIO. Then, the test generator generates the final test pattern in the form of the scrip for controlling the test from the tester 2 or the I2C controller etc by use of the operation model 23 of the I2C component and the I2C tree 25.

(1) Open-Circuit/Short-Circuit Test

(1. 1) Process of JTAG Component

The test generator acquires the driving/receiving information per bit of the JTAG component on the bit-by-bit from the head. Then, the test generator sets the acquired driving/receiving information per component pin in relevant positions of a TDI/TDO array from the cell sequence information of the respective pins on the basis of the BSDL information with respect to the JTAG. Herein, the TDI/TDO array is an array of boundary cell connecting image. For example, the TDI/TDO array can be stored with the data for updating the output pin and the expected value of the data captured from the input pin.

The test generator performs JTAG state control or outputs the bit string of the TDI/TDO array upon finishing the conversion of one parallel test pattern, thereby generating the final test pattern for the JTAG interface. The JTAG state control is a command for controlling the JTAG component and includes, e.g., updating the data, shifting the data, capturing the data, etc. The sequence of controlling the JTAG component is specified in the JTAG, and hence its detailed description is omitted.

(1. 2) Process of I2C Component

The signals of the I2C component are input and output on the PIO port basis. Accordingly, the test generator generates the test pattern of the PIO port per component from the parallel test pattern set in the pin. In greater detail, it is specified from the information per pin of the parallel test pattern which component, which port and which bit position are used for insertion into the port data by referring to the I2C model on the basis of the component name and the pin. The PIO test pattern will hereinafter be referred to also as the port data.

Then, the test generator, in the case of converting the test pattern of the PIO connected to, e.g., the multiplexer, sets the control information for the I2C-MPX at the stage previous to the I2C-PIO being processed underway. For instance, the test generator selects the I2C-MPX (MPX at the 0-th stage) having the Acsn coincident with the first two characters (port number) of the Acsn of the I2C-PIO being processed underway. Then, the test generator obtains the connection channel on the basis of the characters of the Acsn subsequent to the Acsn of the I2C-PIO being processed underway. Next, the test generator sets the control information for selecting the connection channel according to the MPX information in the operation model 23 of the I2C component. The same procedure being repeated, the test generator sets the channels up to the I2C-MPX just before the I2C-PIO being processed underway. The control information for outputting the data to the acquired channel is called selective designation.

At this point of time, the data of the PIO port of the component of the I2C-PIO being processed underway are determined. That is, the I/O direction, the output value and the input expected value are determined on the bit (pin) basis of the PIO port. Thereupon, the test generator sets the input and the output to the directional register of the I2C-PIO being processed underway on the basis of the information of the CONF subcommand in the operation model of the I2C component.

Next, the test generator sets the output level (1/0) to the output register on the basis of the information of the OUT subcommand in the operation model 23 of the I2C component from the parallel test pattern (port data) for driving the pin. Similarly, the test generator sets the control information for the parallel test patterns (port data) of the PIO of all the components.

The test generator similarly sets the parallel test pattern received from the component pin. Namely, the test generator sets the control information for the high-order I2C-MPX with respect to the PIO that receives the parallel test pattern. Then, the test generator sets the directional register based on the information of the CONF subcommand of the I2C model as well as being based on the parallel test pattern (port data) of the PIO (pin) of the I2C-PIO being processed underway. Next, the test generator outputs the control information for designating the read from the input register, the expected data and mask data for ignoring the bits other than the input from the information of the I2C model and the port data. The mask data is a bit string designated per pin for distinguishing between the pin with the read being designated and the pin other than the read-designated pin.

The test generator executes the processes described above with respect to the PIO of all the components set in the parallel test patterns. Moreover, the test generator executes the processes described above for all the test patters, thereby generating the final test pattern of the open-circuit/short-circuit test.

(2) I2C Function Test

The test generator sets, in the same way as in the case of the PIO, the I2C-MPX at the stage previous to that I2C voltage measurement component for testing this component from within the parallel I2C function test. Then, the test generator converts a start of the voltage measurement and setting of a range into actual commands (I2C write) and the read of the voltage into an actual command (I2C read). As for the I2C-ROM, the test generator sets the address designated by a ROM type (I2C write) and generates the data read command (I2C read). As for checking the data, the test generator generates a command given to the tester 2 so as to perform the test in a way that makes a comparison with the data designated beforehand.

<<Example of Final Test Pattern Generation Process>>

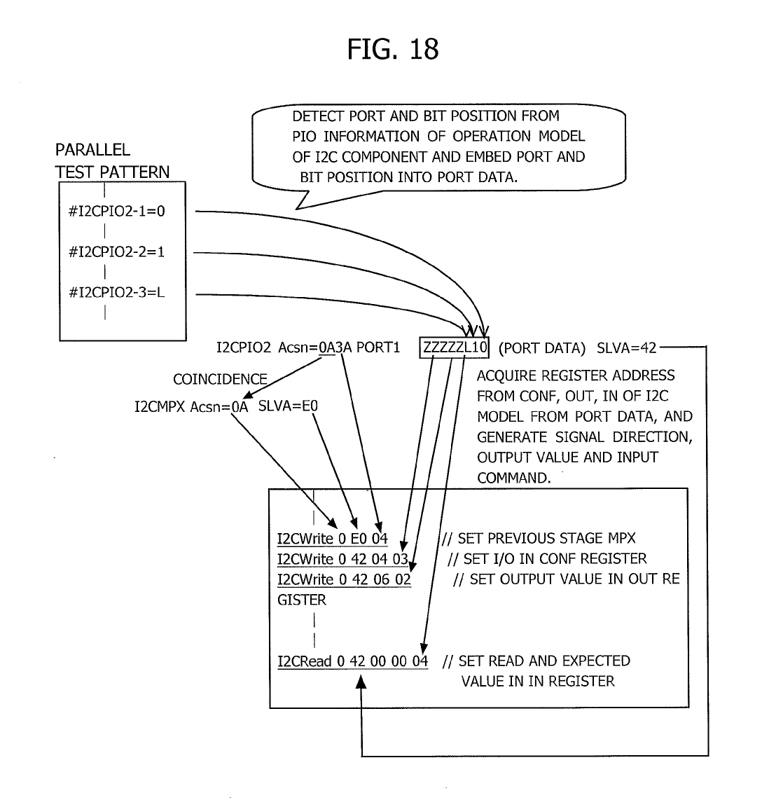

FIG. 18 illustrates a flow of the data in a final test pattern generation process. Herein, the final test pattern generation process is exemplified as the parallel test patterns by taking a case of setting the following items for example. Further, an assumption is that the component named I2C-PIO2 is, as depicted in FIG. 2, connected to the component, i.e., the multiplexer I2C-MPX by way of the components on the printed circuit board 9.

#I2CPIO2-1=0;

This pattern is the parallel test pattern indicating that the level “0” is written to the pin P1 of the component I2C-PIO2.

#I2CPIO2-2=1;

This pattern is the parallel test pattern indicating that the level “1” is written to the pin P2 of the component I2C-PIO2.

#I2CPIO2-3=L;

This pattern is the parallel test pattern indicating that the designation of the read from the pin P3 of the component I2C-P102 and the expected value of the readout value are “L” (low electric potential, ground potential). With respect to these parallel test patterns, the test generator acquires the relevant port and the bit position from the PIO information of the operation model 23 of the I2C component, and generates and records the port data in the way of being associated with the pin corresponding to each bit position. For example, the three parallel test patterns become the port data given below.

I2CPIO2 Acsn=0A3A PORT1 ZZZZZL10 SLVA=42;

Herein, the PORT1 is the port name. Normally if the PIO of the I2C component has a bit count exceeding, e.g., 8 bits, the PIO is bitwise disposed in separation into a plurality of ports, whereby the port names are defined and the bits separated by the port names are specified. Such being the case, the port data is defined per port of each component.

Moreover, “ZZZZZL10” is the parallel test pattern set in each of the pins P7-P0. Further, e.g., “Z” is a character indicating that the parallel test pattern is not set. This parallel test pattern indicates that the expected data of the read from the pin P2 is “L” (low electric potential, ground potential), the level of the write from the pin P1 is “1”, and the level of the write from the pin P0 is “0”.

The test generator selects the MPX at the 0-th stage and the tester channel “0” from the high-order two characters “0A” of Acsn=0A3A. Note that the test generator calculates the slave address of each I2C component when generating the I2C tree 25 and sets the slave address in, e.g., the I2C component table 24 (or the I2C tree 25) in the present working example. Thereupon, the test generator acquires the slave address, e.g., “E0” of the MPX at the 0-th stage, which is set in the I2C component table 24. Moreover, the test generator makes a recognition of being connected to the channel 3 of the MPX at the 0-th stage from the third character “3” of Acsn=0A3A. Then, the test generator acquires the set value (e.g., “04”) in the channel selection register for selecting the channel 3 from the set value given by “sel=” of the MPX subcommand in the operation model 23 of the I2C component. Subsequently, the test generator generates the following commands as the control information. The control information is the macro command used for the tester 2 to control the I2C-MPX on the printed circuit board 9.

I2CWrite 0 E0 04;

Next, the test generator sets the directional register (CONF) of the component I2C-PIO2. Now, it is supposed that the slave address of the component I2C-P102 is “42” and the address of the directional register (CONF) is “04”. Further, the pins P1, P0 corresponding to the low-order 2 bits are the write pins, while the pin P2 corresponding to the third bit counted from under is the read pin. Moreover, the pins P7-P3 have no designation of the parallel test pattern (port data “Z”). Thereupon, the set value in the directional register becomes “03” because of setting the bit “1” indicating “write” is set in the low-order 2 bits. Accordingly, the test generator generates the following control information as the final pattern.

I2CWrite 0 42 04 03;

Similarly, the address of the output register (OUT) is “06”, the value written to the output register (OUT) is the low-order 2 bits such as “1” and “0”, and hence the value becomes “02” in hexadecimal number. Then, the test generator generates the following control information as the final pattern.

I2CWrite 0 42 06 02;

Likewise, the address of the input register (IN) is “00”, the expected data of the pin P2 (the third bit from under) from the input register (IN) is “L”, while other bits are not yet set with the result that the bits are “00” (all the bits are “0”), and the mask is “04” because of the third bit from under being “1”. Thereupon, the test generator sets the following control information in the final pattern.

I2CRead 0 42 00 00 04;

Note that the expected data and the mask data are used for verifying the data read from the input register of the test target I2C component. That is, the tester 2 acquires the port data from the input register of the test target I2C component. Then, the tester 2 selects the data of the input pin from the acquired port data by use of the mask and compares the selected data with the expected data, thereby implementing the test.

The test generator outputs the control information generated in the procedure described above as the final test pattern (refer to the open-circuit/short-circuit in FIG. 9).

<<Processing Flow of Generating Final Test Pattern>>

(1) Final Open-Circuit/Short-Circuit Test Pattern

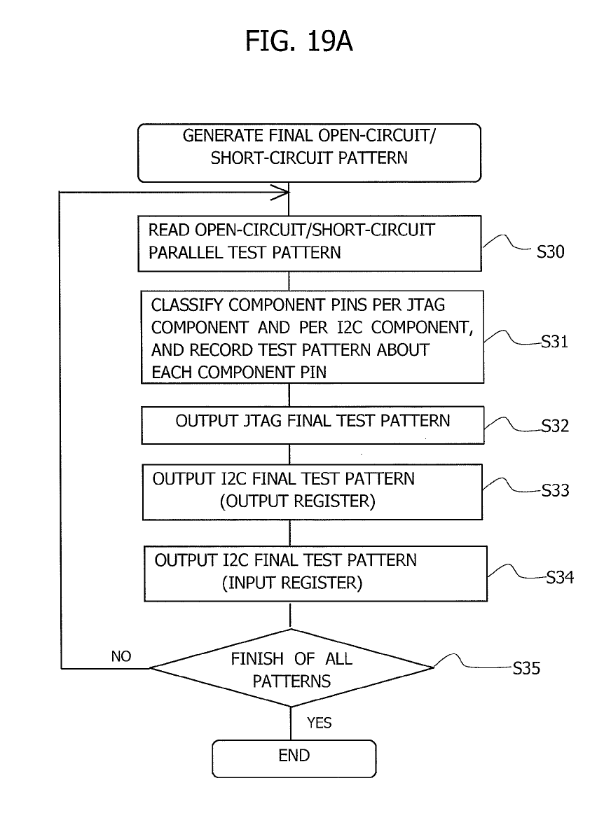

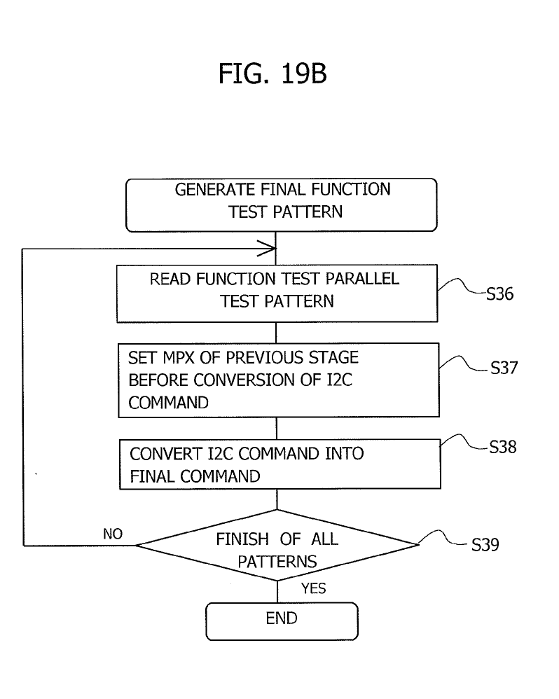

FIG. 19A illustrates a processing flow of generating the final test pattern. In this process, the test generator, to start with, reads the parallel test pattern (S30). Then, the test generator classifies the pins in the parallel test pattern according to the types of the components, and records the pins of the I2C component in the respective pieces of port data and the pins of the JTAG component in the TDI/TDO array (S31). The port data are generated by the process in S31.

Upon finishing reading the parallel test pattern for one pattern, the test generator outputs the final test pattern on the basis of the test pattern set in the JTAG component, i.e., the data recorded in the TDI/TDO array (S32). This process is a process of generating, with the TDI/TDO array containing a record of the information set in the boundary cells corresponding to the pins of the JTAG component and a record of the expected value information for the readout information for one step of the test pattern, the test pattern for setting the output pins by shifting in from the TDI on the basis of these records of information. This process is also a process of generating inspection data on the basis of the bit string captured from the input pins and observed at the TDO. Details of the JTAG final test pattern output process are omitted.

Next, the test generator outputs the final test pattern for the test pattern set in the pins of the I2C component. In the present working example, however, the test generator outputs the final test patterns separately to the output register, i.e., as the I2C write pattern and to the input register, i.e., as the I2C read pattern. For instance, the test generator outputs the final test pattern to the output register of the I2C component (S33). Further, the test generator outputs the final test pattern to the input register of the I2C component (S34). This process is repeatedly executed for all the patterns (S35).

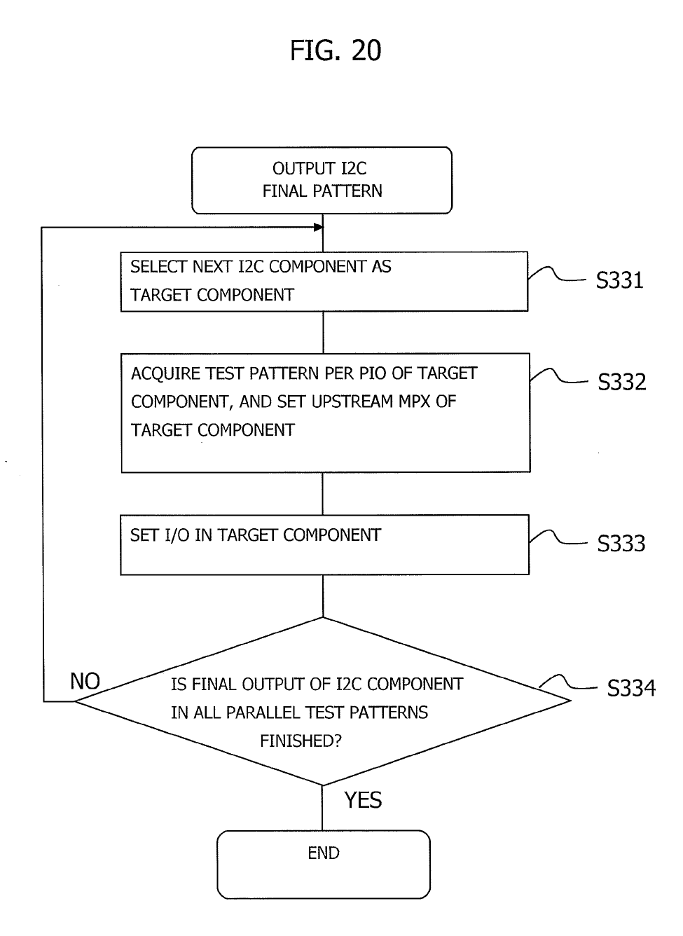

FIG. 20 illustrates in detail the I2C final test pattern output process (S33 in FIG. 18). Herein, the I2C final test pattern output process to the output register will be exemplified. For example, the test generator, when starting the I2C final test pattern output process in the process of S33, receives a designation of the process with respect to the output register as a parameter when started. Then, the test generator executes the following process for all the PIO ports of the I2C components recorded in the process of S31.

In this process, the test generator sets one of the I2C components recorded in the process of S31 as a next target component (S331). Then, the test generator sets the I2C-MPX at the previous stage per PIO of the target component (S332). Specifically, the test generator acquires the I2C-MPX (MPX at the 0-th stage) having the Acsn coincident with the first two characters of self-Acsn of the PIO of the target component being processed underway. Moreover, the test generator acquires the channel of I2C-MPX by reading the characters (connection channel) subsequent next to the first two characters of the Acsn of the target component. Then, the test generator sets the control information for selecting the acquired channel according to the information of the MPX subcommand of the operation model 23 of the I2C component. Similarly, the test generator sequentially sets the I2C-MPX of the stagenext to the 0-th stage. Subsequently, the test generator sets the channels up to the I2C-MPX just before the target component.

In the process described above, the test generator sets the channels of the MPX just before the target component from the MPX at the 0-th stage. Further, in the process of S31 in FIG. 19A, the test generator determines the port data per component. Thereupon, the test generator sets the input/output according to the port data of the target component (S333). More specifically, the test generator generates the control information for performing the setting in the directional register on the basis of the information of the CONF subcommand of the operation model of the I2C component. Moreover, the test generator acquires the address of the output register on the basis of the information of the OUT subcommand of the operation model of the I2C component. The test generator generates the control information for setting the output level in the output register according to the port data of the target component port.

Next, the test generator determines whether the final test output of the port data of all the I2C components with the parallel test patterns being set is finished or not (S334). Then, if it is determined in S334 that all the output is not yet finished, the test generator loops the control back to S331. Whereas if all the output is finished, the test generator terminates the processing.

Note that FIG. 20 illustrates an I2C final test pattern output process to the output register, however, the I2C final test pattern output process to the input register is the same (S34 in FIG. 18). For example, the test generator, similarly to S332, sets the I2C-MPX with respect to the PIO of each component and generates the control information for setting the reading from the input register on the basis of the information of the IN subcommand of the operation model of the I2C component from the port data. Still further, the test generator generates the control information for reading from the IN register in accordance with the port data of the target component port. Moreover, the test generator may output the mask data for ignoring the bits other than the expected data for the data read from the IN register and the input.

(2) Final I2C Function Test Pattern

FIG. 19B illustrates a final I2C function test generation flow. The test generator at first reads one command from the parallel I2C function pattern (S36). Then, if this command is the I2C control command, the test generator sets the I2C-MPX at the stage previous to that component (S37). This setting is done from the field containing the description of the component name of the command in the same way as performing the setting in the open-circuit/short-circuit test. Next, the I2C control command is converted into a final command (S38). The I2C command includes starting the voltage measurement, reading the voltage, setting the expected value thereof and the range, and further reading from the I2C-ROM. Namely, it may be considered that the I2C command contains only the descriptions of the component pins and the parameters (the expected value and the range) for the setting. Such being the case, the test generator accesses the I2C component table on the basis of the component name, and calculates the tester channel, the slave address and the address of the setting register and further the actual set value from the parameters, thereby generating the final command. All the patterns (commands) are processed in the procedure such as this (S39).

<Implementation of Test and Analysis of Failure>

The tester 2 translates the generated final test pattern into the bit string, and drives, e.g., the JTAG interface and the I2C interface via tester pins. Then, the tester 2 tests the printed circuit board 9 by reading the values that are output from the JTAG interface and the I2C interface. If the error occurs in the JTAG component, the tester 2 outputs the following items of information.

(1) Information indicating which step of the test pattern the error occurs.

(2) Information of the component pin with the error being detected, the net name, the readout level and the expected value.

In the error detected in the test of the I2C component, there are displayed the test pattern number, the component name, the PIO name, the readout 1-byte content, the byte value of the expected value per component and the mask value. In the present working example, however, it is feasible to display the net name, the component pin and the readout bit value, and the expected bit value on the basis of the error bit from the associations between the nets and the ports generated by the test generator.

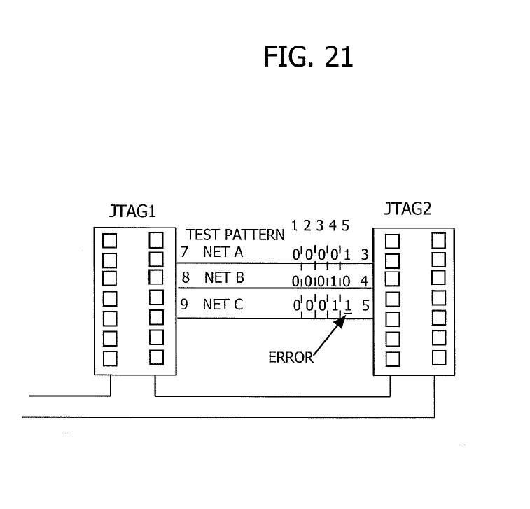

FIG. 21 is a diagram illustrating the short-circuit of the net connecting the pins of the JTAG component. In the JTAG test, the test program is automatically generated. Therefore, the information processing apparatus 1 or the tester 2 includes the test patterns for the pins of the respective components in the form of the test database 28 as in FIG. 17. Accordingly, the information processing apparatus 1 or the tester 2 can point out the short-circuit between the nets and the open-circuit of the net owing to the failure analysis function using the test database 28.

For example, in FIG. 21, such a case is assumed that the error is detected by reading “0” with the pin 5 of the JTAG2 in the fifth test pattern. It is now presumed that the input value from the receiving pin is different from the drive value in the fifth test pattern of the net C on the basis of the comparison with the expected data, and the tester 2 detects the error. Further, the tester 2 searches for the net in which the fifth bit value of the test pattern is different from that of the test pattern of the net C, and other bits of the test pattern are the same as those of the test pattern of the net C. Thereupon, it is assumed that net B is detected. In this case, the information processing apparatus 1 or the tester 2 can point out that the nets C and B are short-circuited.

As described above, in the present working example, similarly to the JTAG component, the net name, the component pins, the read value and the expected value are acquired from the error information with respect to the I2C component, and the test database 28 and the I2C component pins are generated in the same way as in the case of the JTAG. Hence, the information processing apparatus 1 or the tester 2 can realize the analysis of the failure even in the I2C circuit or the JTAG/I2C mixture circuit.

<Effects>

The test generator in the present working example is characterized by including mainly the following six processes and automatically generating the test program of the I2C circuit based on the modeling of the I2C component. The test generator in the present working example can generate the test program for the printed circuit board 9 of the I2C component or the test program for the printed circuit board 9 mounted with the JTAG component and the I2C component in mixture, which cannot be realized by the conventional test generators.

(1) Operation Model of I2C Component

The test generator in the present working example is based on the premise of setting the operation model 23 of the I2C component. Namely, the test generator reads the settings in the operation model 23 of the I2C component into the data structure on the main memory, and executes generating the I2C component table 24 and the I2C tree 25. That is, the operation model 23 of the I2C component enables expression of the operation of the I2C component and enables the generation of the test program for the printed circuit board 9 including the I2C components by generating the I2C connection tree for controlling the I2C components.

(2) Generation of Test Access Information

The test generator generates the I2C component table 24 by referring to the operation model 23 of the I2C component from the net list 21. The I2C component table 24 contains the component names and the pointers to the I2C models. The I2C component table 24 enables the test generator to recognize the unknown component, i.e., the I2C component. Further, the test generator automatically recognizes the I2C tree 25 on the basis of the net list 21 and the operation model 23 of the I2C component. Then, the test generator stores the slave addresses in the I2C tree 25 or the I2C component table 24, and can generate the information for the I2C control.

Moreover, the test generator in the present working example can extract the input pin and the output pin from the pin fields of the net list 21 and the operation model 23 of the I2C component. Accordingly, the test generator in the present working example can, similarly to the JTAG component, get the PIO pins of the I2C component contained in the test access information 26, and can set the circuit including the I2C component as the test target circuit.

(3) Generation of Parallel Test Pattern

The test generator in the present working example generates, similarly to the JTAG test generator, the parallel test pattern for the test access information 26. Further, the test generator in the present working example generates also the test database 28 in generating the parallel test pattern. The parallel test pattern is used for generating the final test pattern, and the test database 28 is used for analyzing the failure. For example, the failure portion can be troubleshoot in the short-circuit test by allocating the bit patterns unique to each other to the respective nets extracted as the test access information 26.

(4) Generation of Final Test Pattern

The test generator in the present working example can generate the final test pattern from the I2C component table 24 and the operation model 23 of the I2C component on the basis of the parallel test patterns.

To be specific, the test generator can generate the final test pattern as the control sequence for the I2C component by the tester 2 for realizing the parallel test pattern in a way that defines the pins belonging to the ports, the I/O directions and the register addresses in the operation model 23 of the I2C component.

Further, the I2C-MPX is included on the printed circuit board 9, in which case also the test generator can generate the final test pattern for setting the channels up to the target I2C component by setting the selection value of the channel selection register in the operation model 23 of the I2C component. As a result, the test generator can generate the final test pattern for testing the target I2C component via the I2C-MPX.

(5) The test generator in the present working example can generate the I2C function test, e.g., the test program for, e.g., the I2C-ADC, I2C-ROM, etc.

(6) Analysis of Failure

In the test for the printed circuit board, when the error occurs, the information processing apparatus 1 or the tester 2 can analyze, because of the test database 28 containing the I2C components being generated, the failure on the basis of the test database 28 containing the I2C components.

### Modified Example

The working example given above has discussed the processing example in which the test generator automatically generates the test program for testing the printed circuit board 9 by preparing the operation model 23 of the I2C component in the printed circuit board 9 mounted with the JTAG component and the I2C component. It does not, however, mean that the processes in the working example described above are limited to the printed circuit board 9 mounted with the JTAG component and the I2C component.

For example, the test generator automatically generates the test program for testing the printed circuit board in the same procedure as in the example 1 with respect to the printed circuit board not mounted with the JTAG component but mounted with the I2C component. Moreover, it is feasible to generate the test program for the printed circuit board mounted with components such as SPI (Serial Peripheral Interface) components other than the I2C component in the same procedure. Namely, the SPI interface specification is stored in the file taking the same format as that of the operation model 23 of the I2C component, and the test generator analyzes an SPI operation model and provides a routine for handling the control of the SPI, whereby the control information may be generated.

<Computer-Readable Recording Medium>

A program for making a computer, other machines and devices (which will hereinafter be referred to as the computer etc) realize any one of the functions can be recorded on a non-transitory recording medium readable by the computer etc. Then, the computer etc is made to read and execute the program on this recording medium, whereby the function thereof can be provided.

Herein, the non-transitory recording medium readable by the computer etc connotes a non-transitory recording medium capable of storing information such as data and programs electrically, magnetically, optically, mechanically or by chemical action, which can be read from the computer etc. Among these non-transitory recording mediums, for example, a flexible disc, a magneto-optic disc, a CD-ROM, a CD-R/W, a DVD, a Blu-ray disc, a DAT, an 8 mm tape, a memory card like a flash memory, etc are given as those removable from the computer. Further, a hard disc, a ROM (Read-Only Memory), etc are given as the non-transitory recording mediums fixed within the computer etc.

Different types of integrated circuits each having a different interface are mounted on the printed circuit board, in which case it is difficult to implement the test. Such being the case, one aspect of an embodiment of the disclosure aims at facilitating implementation of a test between integrated circuits with respect to an electronic device mounted with the integrated circuit including an interface based on a predetermined specification and the integrated circuit including an interface having a specification different from the predetermined specification.

The embodiments discussed herein can easily implement the test between the integrated circuits with respect to the electronic device mounted with the integrated circuit having the interface based on the predetermined specification and the integrated circuit having the interface different from the predetermined specification.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An information processing apparatus comprising:
a storage unit of connection information indicating a connecting relation between pins of an integrated circuit within an electronic device including a first integrated circuit and a second integrated circuit;
a first operation model storage unit to contain at least one of a designation of an output pin for outputting data to the outside of the first integrated circuit and a designation of an input pin for inputting data from the outside of the first integrated circuit;
a second operation model storage unit to contain at least one of a designation of an output pin for outputting data to the outside of the second integrated circuit and a designation of an input pin for inputting data from the outside of the second integrated circuit; and
a test access information extracting unit to extract, from the storage unit of the connection information, the connecting relation containing both of the output pin and the input pin as test access information defined as information of a test-enabled net and a test-enabled pin in the connecting relations between the pins within the electronic device including the first integrated circuit and the second integrated circuit.

2. The information processing apparatus according to claim 1, further comprising a test pattern generation unit to allocate bit strings different from each other to a plurality of connecting relations extracted as the test access information.

3. The information processing apparatus according to claim 1, wherein the second integrated circuit has at least a pair of communication pins,
the second operation model storage unit includes an interface specification for inputting and outputting the data to the input pin and the output pin of the second integrated circuit via the communication pins, and
the information processing apparatus further comprises a generation unit to generate control information for transferring and receiving the data to and from the first integrated circuit pursuant to a predetermined specification and to generate control information pursuant to the interface specification for executing at least one of writing the data to the output pin and reading the data from the input pin via the communication pins.

4. The information processing apparatus according to claim 3, wherein the electronic device includes a third integrated circuit having channel communication pins of a plurality of channels that are switched over to be connected to any of the communication pins of a plurality of second integrated circuits,
the storage unit of the connection information further contains connection information indicating the connecting relation between the pins including the channel communication pins,
the second operation model storage unit contains selective designation information for selecting one piece of channel communication pin from within the plurality of channels, and
the generation unit generates, based on the selective designation information, a selective designation to select the channel communication pin of the third integrated circuit existing as an intermediary circuit in a midway path extending from an external connection point for establishing a connection to the outside of the electronic device up to the communication pin of the second integrated circuit on the electronic device.

5. The information processing apparatus according to claim 4, wherein each of the channel communication pins of the plurality of channels is connectable in divergence to the respective communication pins of the plurality of integrated circuits including the second integrated circuit or the third integrated circuit, the second operation model storage unit further contains calculation information of respective addresses for identifying the plurality of integrated circuits including the second integrated circuit or the third integrated circuit,
the information processing apparatus further comprises an address calculation unit to calculate the respective addresses of the plurality of integrated circuits including the second integrated circuit or the third integrated circuit in accordance with the address calculation information, and
the generation unit designates the calculated address of the second integrated circuit in the control information pursuant to the interface specification and sets the calculated address of the third integrated circuit in the selective designation for selecting the channel communication pin of the third integrated circuit.

6. The information processing apparatus according to claim 1, wherein the electronic device further includes a fourth integrated circuit having the communication pins,
the second operation model storage unit further contains a control specification for acquiring data from an internal circuit of the fourth integrated circuit via the communication pins, and
the generation unit generates the control information for acquiring the data from the internal circuit via the communication pins in accordance with the control specification.

7. The information processing apparatus according to claim 1, wherein the first integrated circuit includes:
a register chain to retain the data transferred to and received from the pins included in the first integrated circuit and to be capable of sequentially shifting the retained data;
a first control input pin to sequentially write the data to the register chain; and
a first control output pin to sequentially read the data from the register chain.

8. A test data generating apparatus to generate test data of an electronic device including a first integrated circuit and a second integrated circuit, the second integrated circuit having at least a pair of communication pins, the test data generating apparatus comprising:
a storage unit of connection information indicating a connecting relation between pins of the integrated circuit within the electronic device including the first integrated circuit and the second integrated circuit;
a first operation model storage unit to contain at least one of a designation of an output pin for outputting data to the outside of the first integrated circuit and a designation of an input pin for inputting data from the outside of the first integrated circuit;
a second operation model storage unit to contain at least one of a designation of an output pin for outputting data to the outside of the second integrated circuit and a designation of an input pin for inputting data from the outside of the second integrated circuit, and to have a definition of an interface specification for inputting and outputting the data to the input pin and the output pin of the second integrated circuit via the communication pin; and
a generation unit to generate control information for transferring and receiving the data to and from the first integrated circuit pursuant to a predetermined specification and to generate control information pursuant to the interface specification for executing at least one of writing the data to the output pin and reading the data from the input pin via the communication pin.

9. A test data generating method of an electronic device, comprising:
acquiring connection information indicating a connecting relation between pins of an integrated circuit within the electronic device including a first integrated circuit and a second integrated circuit from a storage unit of the connection information;
acquiring first operation model information from a first operation model storage unit containing at least one of a designation of an output pin for outputting data to the outside of the first integrated circuit and a designation of an input pin for inputting data from the outside of the first integrated circuit;
acquiring second operation model information from a second operation model storage unit containing at least one of a designation of an output pin for outputting data to the outside of the second integrated circuit and a designation of an input pin for inputting data from the outside of the second integrated circuit; and
extracting the connecting relation containing both of the output pin and the input pin as test access information defined as information of a test-enabled net and a test-enabled pin in connecting relations indicated by the acquired connection information.

10. The test data generating method of the electronic device according to claim 9, further comprising allocating bit strings different from each other to a plurality of connecting relations extracted as the test access information.

11. The test data generating method of the electronic device according to claim 9, wherein the second integrated circuit has at least a pair of communication pins, the second operation model information contains an interface specification for inputting and outputting the data to the input pin and the output pin of the second integrated circuit via the communication pins, further comprising:
first generating control information for transferring and receiving the data to and from the first integrated circuit in accordance with a predetermined specification; and
second generating the control information pursuant to the interface specification for executing at least one of writing the data to the output pin and reading the data from the input pin via the communication pins.

12. The test data generating method of the electronic device according to claim 11, wherein the electronic device includes a third integrated circuit having channel communication pins of a plurality of channels that are switched over to be connected to any of the communication pins of a plurality of second integrated circuits,
the storage unit of the connection information further contains connection information indicating the connecting relation between the pins including the channel communication pins,
the second operation model information contains selective designation information for selecting one piece of channel communication pin from within the plurality of channels, and
the second generating includes generating a selective designation for selecting the channel communication pin of the third integrated circuit existing as an intermediary circuit in a midway path extending from an external connection point for establishing a connection to the outside of the electronic device up to the communication pin of the second integrated circuit on the electronic device.

13. The test data generating method of the electronic device according to claim 12, wherein each of the channel communication pins of the plurality of channels is connectable in divergence to the respective communication pins of the plurality of integrated circuits including the second integrated circuit or the third integrated circuit, the second operation model information contains calculation information of respective addresses for identifying the plurality of integrated circuits including the second integrated circuit or the third integrated circuit, further comprising calculating the respective addresses of the plurality of integrated circuits including the second integrated circuit or the third integrated circuit in accordance with the address calculation information, and
the second generating including:
designating the calculated address of the second integrated circuit in the control information pursuant to the interface specification; and
settings the calculated address of the third integrated circuit in the selective designation for selecting the channel communication pin of the third integrated circuit.

14. The test data generating method of the electronic device according to claim 9, wherein the electronic device further includes a fourth integrated circuit having the communication pins,
the second operation model storage unit further contains a control specification for acquiring data from an internal circuit of the fourth integrated circuit via the communication pins, and
the second generating includes generating the control information for acquiring the data from the internal circuit via the communication pins in accordance with the control specification.

15. A test data generating method to generate test data of an electronic device including a first integrated circuit and a second integrated circuit, the second integrated circuit having at least a pair of communication pins, comprising:
acquiring connection information indicating a connecting relation between pins of the integrated circuit within the electronic device including the first integrated circuit and the second integrated circuit from a storage unit of the connection information;
acquiring first operation model information from a storage unit of the first operation model information containing at least one of a designation of an output pin for outputting data to the outside of the first integrated circuit and a designation of an input pin for inputting data from the outside of the first integrated circuit;
acquiring second operation model information from a storage unit of the second operation model information containing at least one of a designation of an output pin for outputting data to the outside of the second integrated circuit and a designation of an input pin for inputting data from the outside of the second integrated circuit, and having a definition of an interface specification for inputting and outputting the data to the input pin and the output pin of the second integrated circuit via the communication pin;
first generating control information for transferring and receiving the data to and from the first integrated circuit pursuant to a predetermined specification; and
second generating control information pursuant to the interface specification for executing at least one of writing the data to the output pin and reading the data from the input pin via the communication pin.

16. A computer-readable recording medium storing a program to cause a computer to execute a integrated circuit test process, comprising:
acquiring connection information indicating a connecting relation between pins of an integrated circuit within an electronic device including a first integrated circuit and a second integrated circuit from a storage unit of the connection information;
acquiring first operation model information from a first operation model storage unit containing at least one of a designation of an output pin for outputting data to the outside of the first integrated circuit and a designation of an input pin for inputting data from the outside of the first integrated circuit;
acquiring second operation model information from a second operation model storage unit containing at least one of a designation of an output pin for outputting data to the outside of the second integrated circuit and a designation of an input pin for inputting data from the outside of the second integrated circuit; and
extracting the connecting relation containing both of the output pin and the input pin as test access information defined as information of a test-enabled net and a test-enabled pin in connecting relations indicated by the acquired connection information.

17. The computer-readable recording medium storing the program according to claim 16, further comprising allocating bit strings different from each other to a plurality of connecting relations extracted as the test access information.

18. The computer-readable recording medium storing the program according to claim 16, wherein the second integrated circuit has at least a pair of communication pins, the second operation model information contains an interface specification for inputting and outputting the data to the input pin and the output pin of the second integrated circuit via the communication pins, further comprising
first generating control information for transferring and receiving the data to and from the first integrated circuit in accordance with a predetermined specification; and
second generating control information pursuant to the interface specification for executing at least one of writing the data to the output pin and reading the data from the input pin via the communication pins.

19. The computer-readable recording medium storing the program according to claim 18, wherein the electronic device includes a third integrated circuit having channel communication pins of a plurality of channels that are switched over to be connected to any of the communication pins of a plurality of second integrated circuits,
the storage unit of the connection information further contains connection information indicating the connecting relation between the pins including the channel communication pins,
the second operation model information contains selective designation information for selecting one piece of channel communication pin from within the plurality of channels, and
the second generating includes generating a selective designation for selecting the channel communication pin of the third integrated circuit existing as an intermediary circuit in a midway path extending from an external connection point for establishing a connection to the outside of the electronic device up to the communication pin of the second integrated circuit within the electronic device.

20. The computer-readable recording medium storing the program according to claim 19, wherein each of the channel communication pins of the plurality of channels is connectable in divergence to the respective communication pins of the plurality of integrated circuits including the second integrated circuit or the third integrated circuit, the second operation model information contains calculation information of respective addresses for identifying the plurality of integrated circuits including the second integrated circuit or the third integrated circuit, further comprising calculating the respective addresses of the plurality of integrated circuits including the second integrated circuit or the third integrated circuit in accordance with the address calculation information, and
the second generating including:
designating the calculated address of the second integrated circuit in the control information pursuant to the interface specification; and
settings the calculated address of the third integrated circuit in the selective designation for selecting the channel communication pin of the third integrated circuit.

21. The computer-readable recording medium storing the program according to claim 18, wherein the electronic device further includes a fourth integrated circuit having the communication pins,
the second operation model storage unit further contains a control specification for acquiring data from an internal circuit of the fourth integrated circuit via the communication pins, and
the second generating includes generating the control information for acquiring the data from the internal circuit via the communication pins in accordance with the control specification.

22. A computer-readable recording medium storing a program to cause a computer to generate test data of an electronic device including a first integrated circuit and a second integrated circuit, the second integrated circuit having at least a pair of communication pins, the program to cause the computer to perform:
acquiring connection information indicating a connecting relation between pins of the integrated circuit within the electronic device including the first integrated circuit and the second integrated circuit from a storage unit of the connection information;
acquiring first operation model information from a storage unit of the first operation model information containing at least one of a designation of an output pin for outputting data to the outside of the first integrated circuit and a designation of an input pin for inputting data from the outside of the first integrated circuit;
acquiring second operation model information from a storage unit of the second operation model information containing at least one of a designation of an output pin for outputting data to the outside of the second integrated circuit and a designation of an input pin for inputting data from the outside of the second integrated circuit, and having a definition of an interface specification for inputting and outputting the data to the input pin and the output pin of the second integrated circuit via the communication pin;
first generating control information for transferring and receiving the data to and from the first integrated circuit pursuant to a predetermined specification; and
second generating control information pursuant to the interface specification for executing at least one of writing the data to the output pin and reading the data from the input pin via the communication pin.
